(19) United States
(12) Patent Application Publication
(10) Pub. No.: US 2007/0252517 A1
(43) Pub. Date: Nov. 1, 2007

(54) Electroluminescent device including an anthracene derivative

(75) Inventors: Zbyslaw R. Owczarczyk, Webster, NY (US); Denis Y. Kondakov, Kendall, NY (US); Muhunthan Sathiosatham, Fairport, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/412,602

(22) Filed: Apr. 27, 2006

(51) Int. Cl. H01L 51/54

(52) U.S. Cl. 313/504; 428/690; 428/917; 313/506; 257/E51.049

(57) ABSTRACT

An OLED device comprises a cathode, an anode, and has therebetween a light emitting layer containing a host material and an emitting dopant material wherein the host includes a monoanthracene compound bearing aromatic groups in the 2-, 9-, and 10-positions and being further substituted or not with electron donating groups sufficient so as to provide an anthracene derivative that exhibits a measured oxidation potential of less than 1.28 V.

### CROSS-REFERENCE TO RELATED APPLICATIONS

This application is cofiled as part of a group of five applications under attorney Docket Nos. 91082, 91926, 92030, 92055, and 92056.

### FIELD OF THE INVENTION

This invention relates to an organic light emitting diode (OLED) electroluminescent (EL) device comprising a layer including at least one anthracene derivative, which can provide desirable electroluminescent properties.

### BACKGROUND OF THE INVENTION

While organic electroluminescent (EL) devices have been known for over two decades, their performance limitations have represented a barrier to many desirable applications. In simplest form, an organic EL device is comprised of an anode for hole injection, a cathode for electron injection, and an organic medium sandwiched between these electrodes to support charge recombination that yields emission of light. These devices are also commonly referred to as organic light-emitting diodes, or OLEDs. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, 30, 322, (1969); and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often greater than 100V.

More recent organic EL devices include an organic EL element consisting of extremely thin layers (e.g. <1.0 μm) between the anode and the cathode. Herein, the term “organic EL element” encompasses the layers between the anode and cathode. Reducing the thickness lowered the resistance of the organic layers and enabled devices to operate at much lower voltage. In a basic two-layer EL device structure, described first in U.S. Pat. No. 4,356,429, one organic layer of the EL element adjacent to the anode is specifically chosen to transport holes, and therefore is referred to as the hole-transporting layer, and the other organic layer is specifically chosen to transport electrons and is referred to as the electron-transporting layer. Recombination of the injected holes and electrons within the organic EL element results in efficient electroluminescence.

There have also been proposed three-layer organic EL devices that contain an organic light-emitting layer (LEL) between the hole-transporting layer and electron-transporting layer, such as that disclosed by C. Tang et al. (J. Applied Physics, Vol. 65, 3610 (1989)). The light-emitting layer commonly consists of a host material doped with a guest material, otherwise known as a dopant. Still further, there has been proposed in U.S. Pat. No. 4,769,292 a four-layer EL element comprising a hole injecting layer (HIL), a hole-transporting layer (HTL), a light-emitting layer (LEL) and an electron-transporting/injecting layer (ETL). These structures have resulted in improved device efficiency.

Since these early inventions, further improvements in device materials have resulted in improved performance in attributes such as color, stability, luminance efficiency and manufacturability, e.g., as disclosed in U.S. Pat. No. 5,061,569, U.S. Pat. No. 5,409,783, U.S. Pat. No. 5,554,450, U.S. Pat. No. 5,593,788, U.S. Pat. No. 5,683,823, U.S. Pat. No. 5, 908,581, U.S. Pat. No. 5,928,802, U.S. Pat. No. 6,020,078, and U.S. Pat. No. 6,208,077, amongst others.

EL devices that emit white light have proven to be very useful. They can be used with color filters to produce full-color display devices. They can also be used with color filters in other multicolor or functional-color display devices. White EL devices for use in such display devices are easy to manufacture, and they produce reliable white light in each pixel of the displays. Although the OLEDs are referred to as white, they can appear white or off-white, for this application, the CIE coordinates of the light emitted by the OLED are less important than the requirement that the spectral components passed by each of the color filters be present with sufficient intensity in that light. Thus there is a need for new materials that provide high luminance intensity for use in white OLED devices.

Anthracene based hosts are often used in EL devices. A useful class of 9,10-di-(2-naphthyl)anthracene hosts has been disclosed in U.S. Pat. No. 5,935,721. Bis-anthracene compounds used in the luminescent layer with an improved device half-life have been disclosed in U.S. Pat. No. 6,534,199 and US 2002/0136922. Electroluminescent devices with improved luminance using an anthracene compound have been disclosed in U.S. Pat. No. 6,582,837. Anthracenes have also been used in the hole-transporting layer (HTL) as disclosed in U.S. Pat. No. 6,465,115. In addition there are other disclosures of using anthracene materials in EL devices, for example, U.S. Pat. No. 5,972,247, JP 2001/097897, JP 2000/273056, US 2002/0048687, WO 2003/060956, WO 2002/088274, WO 2003/087023, EP 0429821, WO 2003/007658, JP 2000/053677, and JP 2001/335516.

K. Kim and coworkers (US 2004/0023060) describe double spiro anthracene derivatives. Among the materials reported are those which have a double spiro group located in the 2-positions of a 9,10 substituted anthracene, although materials of this nature may have a large number of carbocyclic rings and may have a high sublimation temperature.

S. Yoon and coworkers, WO 2003/060956, describe anthracene materials in which one to two imidazole groups are located in the 2 or 2,6-positions of 9,10 substituted anthracenes. I. Hidetsugu et al., JP 2004/059535, describe similar 9,10 substituted anthracene in which aryl and heteroaryl groups are located in the 2- or 2,6-positions.

I. Hidetsugu and coworkers, JP 2005/170911, further report anthracene materials substituted in the 2-position with a phenyl group. The phenyl group is substituted in the ortho-position with an aryl group. Illustrative compounds are substituted with the same substituent in the 9- and 10-positions.

I. Hidetsugu et al., JP 2001/335516 also report the use of substituted anthracenes as hosts for light-emitting materials. Examples are described in which the use of anthracenes substituted with simple biphenyl groups in the 9,10-positions afford inferior light-emission relative to more complex anthracenes having biphenyl groups that are further substituted.

S. Conley, W. Vreeland, and L. Cosimbescu, US 2005/211958, describe anthracene compounds bearing at least one aryl ring in the 2-position and having a hydrogen or an alkyl group in the 6-position and having up to 12 aromatic carbocyclic rings including at least one naphthalene group in the 9-position of the anthracene group and an aryl group in the 10-position.

However, anthracenes that have been described previously may not provide all the desirable embodiments of a host material. In particular it would be desirable to have new materials that would afford lower drive voltage or higher luminance or both in EL devices.

### SUMMARY OF THE INVENTION

The invention provides an OLED device comprising a cathode, an anode, and having therebetween a light emitting layer containing a host material and an emitting dopant material wherein the host includes a monoanthracene compound bearing aromatic groups in the 2-, 9-, and 10-positions and being further substituted or not with electron donating groups sufficient so as to provide an anthracene derivative that exhibits a measured oxidation potential of less than 1.28 V. Typical embodiments evidence one or more improved properties such as reduced drive voltage and improved efficiency.

### BRIEF DESCRIPTION OF THE DRAWINGS

FIG. 1 shows a schematic cross-sectional view of an OLED device that represents one embodiment of the present invention.

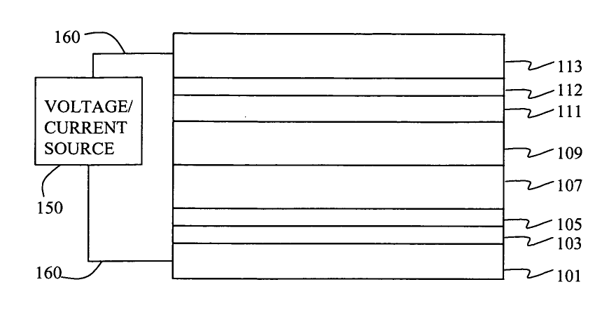

### DETAILED DESCRIPTION OF THE INVENTION

The invention is generally summarized above. The invention provides for a multilayer electroluminescent device comprising a cathode, an anode, at least one light-emitting layer (LEL). The light-emitting layer contains a host material and an emitting material. The host material includes an anthracene derivative. Desirably the anthracene derivative has only one anthracene nucleus in order to keep the synthetic route simple and to avoid high sublimation temperatures. The monoanthracene nucleus is substituted in the 2-, 9-, and 10-positions positions with aromatic groups and may be further substituted. The aromatic groups are directly bonded to the anthracene nucleus. Examples of useful aromatic groups include naphthyl groups, such as 1-naphthyl and 2-naphthyl as well as biphenyl groups, such as 4-biphenyl and 3-biphenyl. The aromatic groups may be further substituted; especially useful substituent groups are electron-donating groups, such as alkoxy groups.

The anthracene derivative exhibits a measured oxidation potential of less than 1.28 V vs. SCE. Oxidation potentials can be measured by well-known literature procedures, such as cyclic voltammetry (CV) and Osteryoung square-wave voltammtry (SWV). For a review of electrochemical measurements, see J. O. Bockris and A. K. N. Reddy, Modern Electrochemistry, Plenum Press, New York; and A. J. Bard and L. R. Faulkner, Electrochemical Methods, John Wiley & Sons, New York, and references cited therein. Oxidation potentials are always reported versus a reference such as the saturated calomel electrode (SCE).

In one suitable embodiment, the anthracene derivative has an oxidation potential of less than 1.25 V, or 1.20 V or less, or even 1.15 V or less vs. SCE. Desirably, the oxidation potential is between 1.10 V and 1.25 V vs. SCE.

In another embodiment the anthracene derivative includes only carbocyclic rings, which may be further substituted with heterocyclic substituents such as, for example, alkoxy groups. The number of rings present are six or greater. In one suitable embodiment, the number of rings present is less than 12 and desirably less than 10 rings.

In certain embodiments it is desirable to include electron-donating substituents on the aromatic rings of the anthracene nucleus in order to achieve the preferred oxidation potential. It is well within the skill of the art to determine whether a particular group is electron donating or electron accepting. The most common measure of electron donating and accepting properties is in terms of Hammett σ values. Hydrogen has a Hammett σ value of zero, while electron donating groups have negative Hammett σ values and electron accepting groups have positive Hammett σ values. Lange's handbook of Chemistry, 12^{th} Ed., McGraw Hill, 1979, Table 3-12, pp. 3-134 to 3-138, here incorporated by reference, lists Hammett a values for a large number of commonly encountered groups. Hammett a values are assigned based on phenyl ring substitution, but they provide a practical guide for qualitatively selecting electron donating and accepting groups.

Particularly useful substituents include those with a sigma para (σp) value more negative than −0.10, −0.15, −0.20, or even more negative than −0.25. However, if the substituent is too electron donating, the electronic properties of the host may be shifted to undesirable ranges and interfere with efficient energy transfer between the host and dopant. Thus in some embodiments it is desirable to have no substituent with a σp value more negative than −0.50.

Examples of useful substituents include alkyl groups, such as methyl groups, ethyl groups, t-butyl groups, neopentyl groups and alkoxy groups, like, for example, a methoxy group and an ethoxy group. In one embodiment, at least one substituent in the 2-, 9-, and 10-positions includes an alkoxy group. In another suitable embodiment, the aromatic group in the 2-position is further substituted with an alkoxy group, such as a methoxy substituent.

In one suitable embodiment, the anthracene nucleus bears a hydrogen or an alkyl group in the 6-position to simplify the synthesis. In a further embodiment, the anthracene nucleus does not bear any substituent with more than two fused rings, such as, for example a phenanthrene group.

In one aspect of the invention, the anthracene derivative is represented by Formula (1).

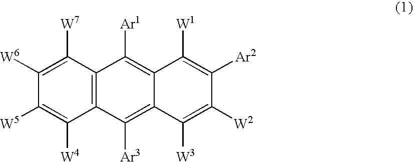

In Formula (1), Ar¹, Ar², and Ar³ are the same or different, and each represents an aromatic group, such as a naphthyl group or a biphenyl group. In one suitable embodiment, at least one of Ar¹, Ar², and Ar³ bears a substituent with a σp value of −0.10 or less, −0.15 or less, −0.20 or less, or −0.25 or less but greater than −0.50. In another desirable embodiment, Ar² represents an aromatic group that bears a substituent with a σp value of −0.25 or lower, such as an alkoxy group, for example a methoxy substituent. In the Formula, w¹ through w⁷ represent hydrogen or a substituent, such as methyl group or a phenyl group. In one suitable embodiment, w⁵ represents hydrogen or an alkyl group.

In a further desirable embodiment the anthracene derivative is represented by Formula (2).

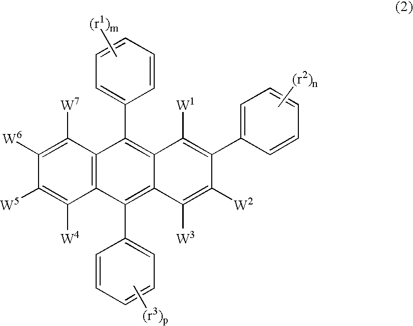

In Formula (2), each r¹, r², and r³ are the same or different, and each represents a substituent group, provided adjacent substituents may combine to form a ring group, and provided at least one of r¹, r², and r³is present and represents a group with a σp value in the range of −0.25 to −0.50, for example a methoxy or ethoxy substituent.

In the Formula, m, n, and p are independently 0-5, provided m, n, and p are not all 0 and w¹ through w⁷ represent hydrogen or a substituent, such as an alkyl group or a phenyl group.

In another aspect of the invention, the anthracene compound is substituted in the 2-, 9-, and 10-positions with aromatic groups and the substituent in the 2-position should have no more than two fused rings, in order to keep the sublimation temperature in a desirable range. In this aspect, the anthracene compound should have an oxidation potential of less than 1.25 V or even less than 1.20 V vs. SCE.

Useful anthracene materials can be synthesized by literature procedures or modifications of such procedures. A useful synthetic route includes that shown in Scheme I.

In Scheme I, Cpd-A represents an anthracene derivative where w¹ through w⁷ have been described previously and Ar² represents an aromatic group. With the proper choice of substituents, Cpd-A can be monobrominated, equation 1, for example by treatment with N-bromosuccinimide, to afford Cpd-B.

The next step, equation 2, involves reacting Cpd-B with an aryl boronic acid, Cpd-C. In the formula of Cpd-C, Ar¹ represents an aromatic group. This reaction is a palladium catalyzed coupling. For examples of this type of coupling reaction, see J. Hassan, M. Sevignon, C. Gozzi, E. Schulz, M. Lemaire, Marc, Chem. Rev, 102, 1359 (2002) and references cited therein and A. F. Litthe, C. Dai, and G. C. Fu, J. Am. Chem. Soc., 122, 4020 (2000).

The product formed in the equation 2 coupling reaction, Cpd-D, can be brominated (equation 3). The resulting bromo compound (Cpd-E) can be subjected to another coupling reaction (equation 4) with a boronic acid derivative, Cpd-F, where Ar³ represents an aromatic group. The final product, Cpd-G, is a material of Formula (1).

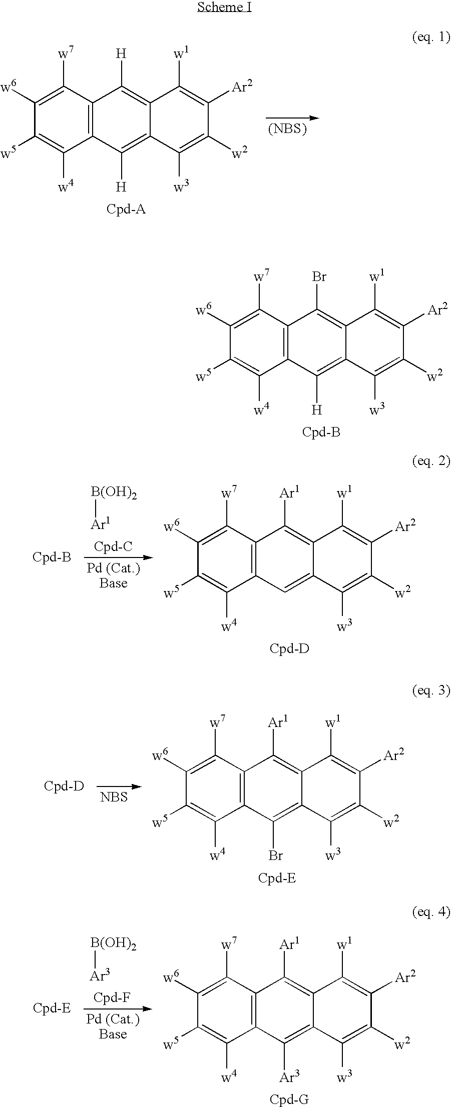

Examples of useful anthracene derivatives are listed below.

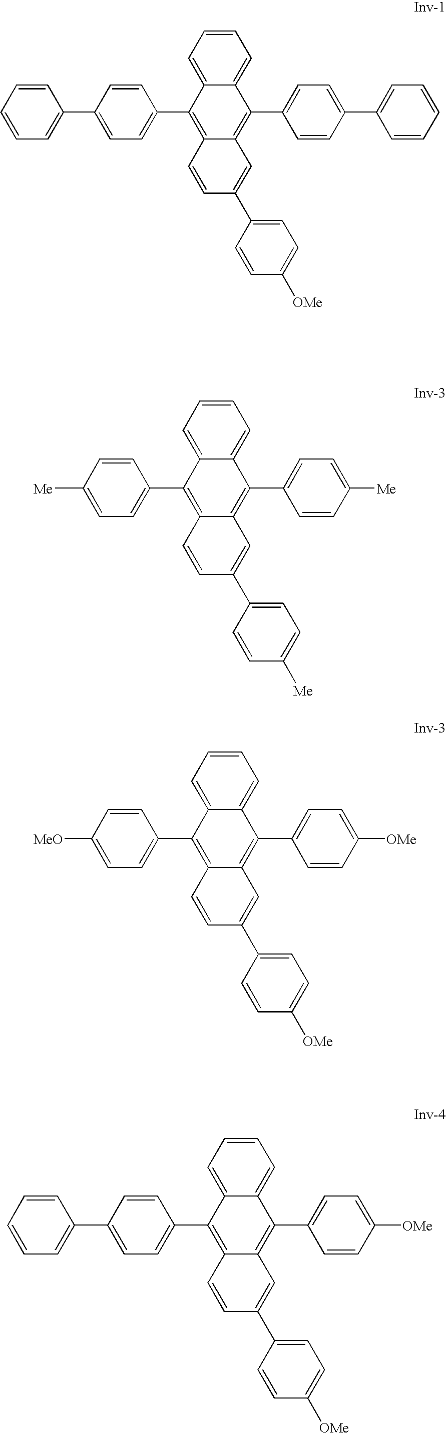

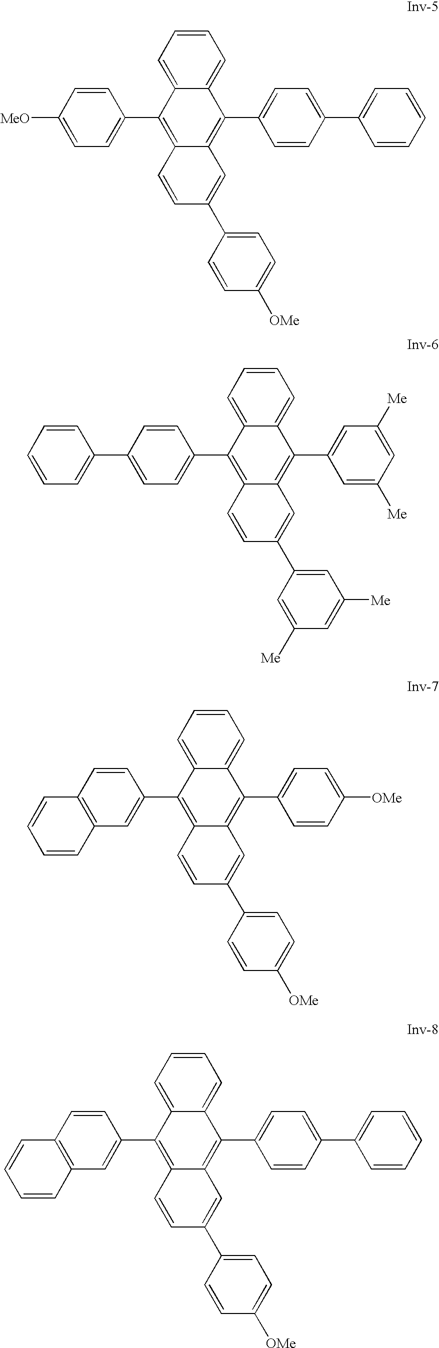

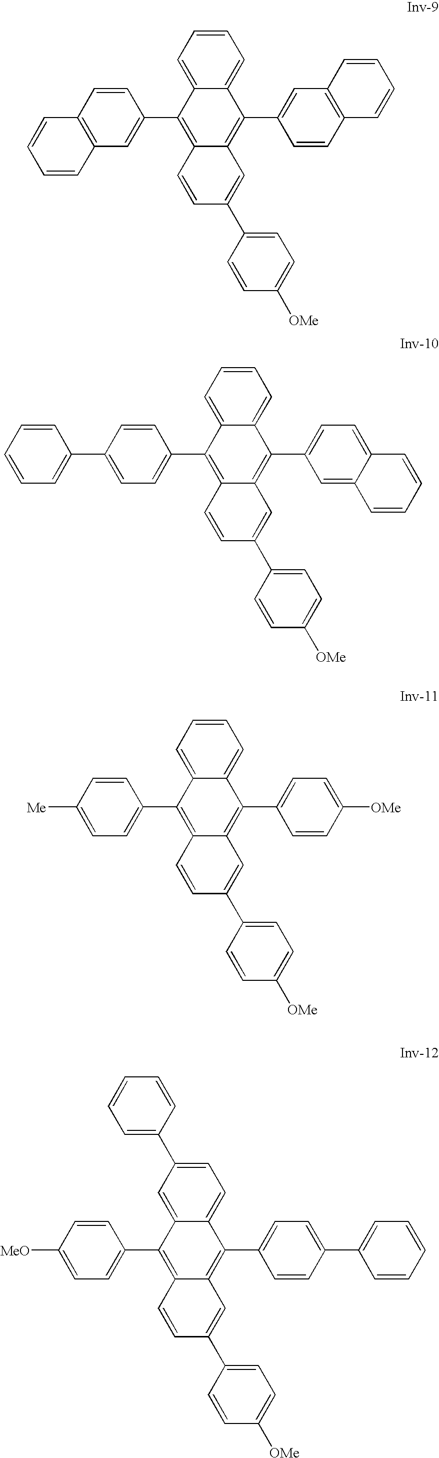

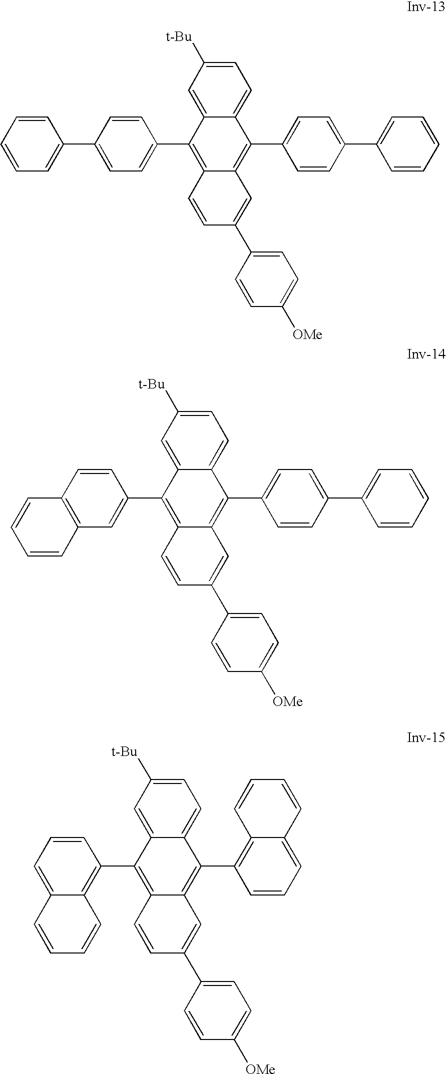

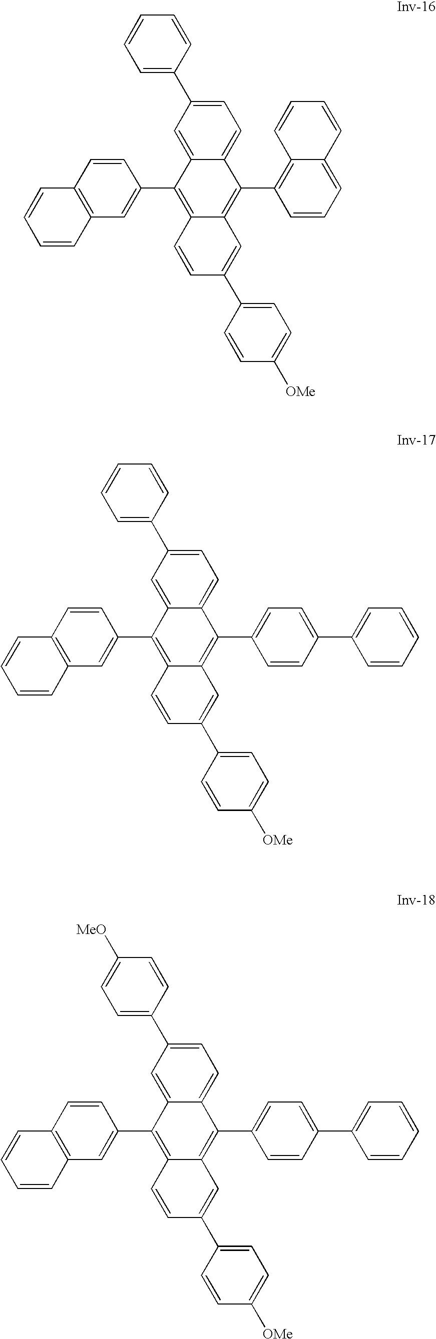

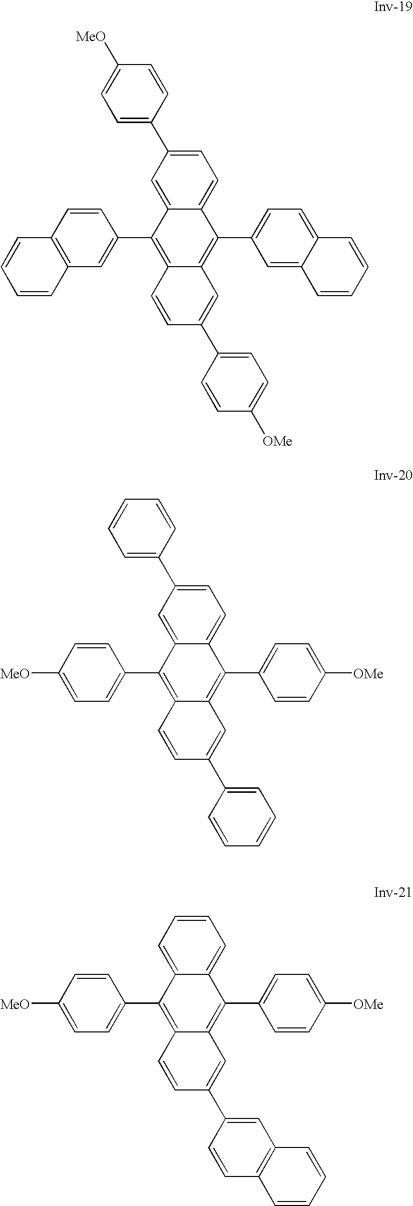

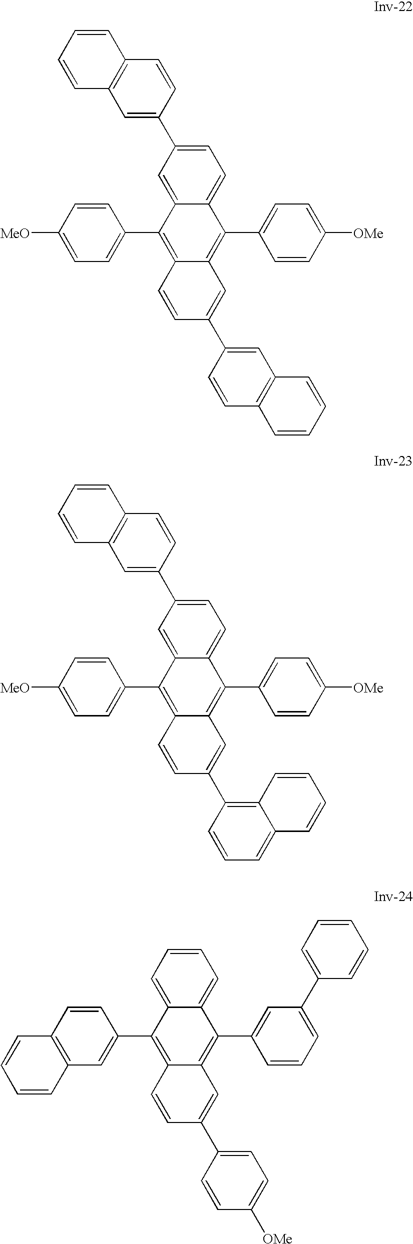

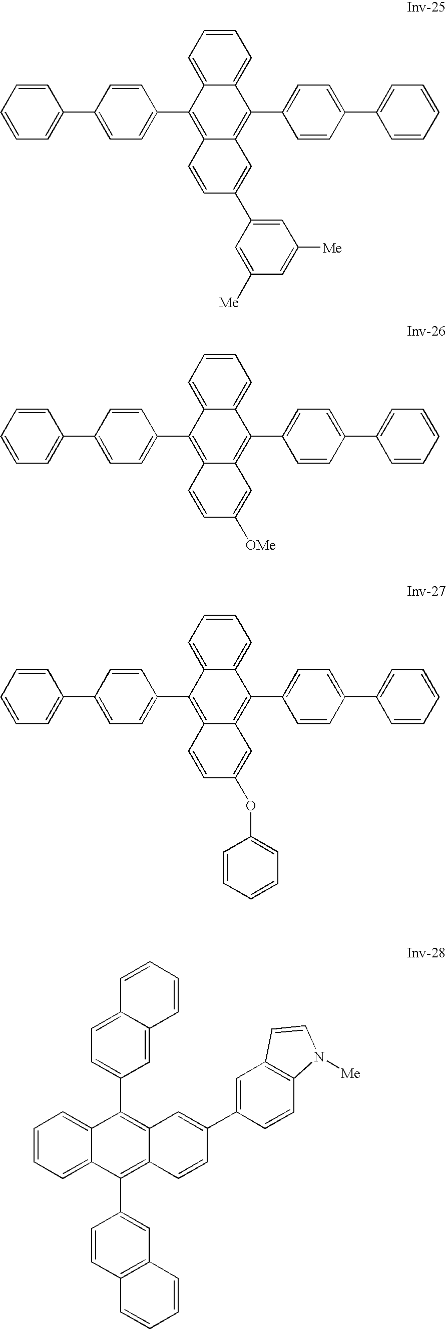

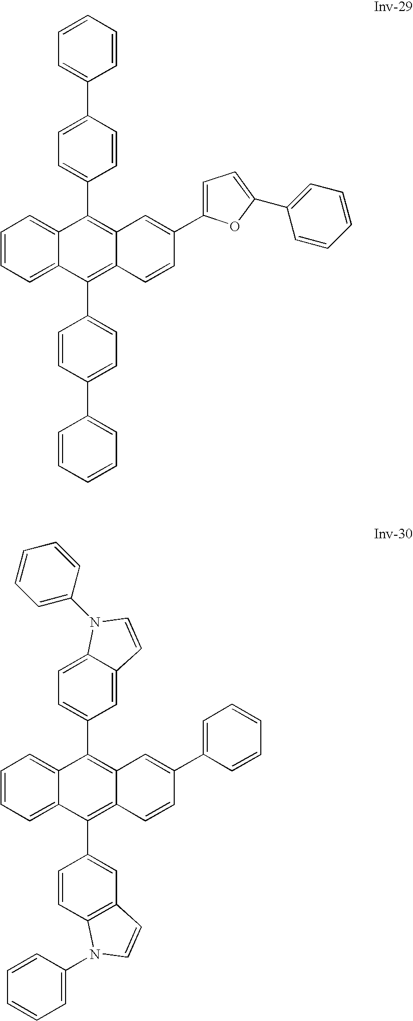

Unless otherwise specifically stated, use of the term “substituted” or “substituent” means any group or atom other than hydrogen. Additionally, unless otherwise specifically stated, when a compound with a substitutable hydrogen is identified or the term “group” is used, it is intended to encompass not only the substituent's unsubstituted form, but also its form further substituted with any substituent group or groups as herein mentioned, so long as the substituent does not destroy properties necessary for device utility. Suitably, a substituent group may be halogen or may be bonded to the remainder of the molecule by an atom of carbon, silicon, oxygen, nitrogen, phosphorous, sulfur, selenium, or boron. The substituent may be, for example, halogen, such as chloro, bromo or fluoro; nitro; hydroxyl; cyano; carboxyl; or groups which may be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonyl amino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropyl-sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur, phosphorous, or boron. Such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain desirable properties for a specific application and can include, for example, electron-withdrawing groups, electron-donating groups, and steric groups. When a molecule may have two or more substituents, the substituents may be joined together to form a ring such as a fused ring unless otherwise provided. Generally, the above groups and substituents thereof may include those having up to 48 carbon atoms, typically 1 to 36 carbon atoms and usually less than 24 carbon atoms, but greater numbers are possible depending on the particular substituents selected.

For the purpose of this invention, also included in the definition of a heterocyclic ring are those rings that include coordinate or dative bonds. The definition of a coordinate bond can be found in Grant & Hackh's Chemical Dictionary, page 91. In essence, a coordinate bond is formed when electron rich atoms such as O or N, donate a pair of electrons to electron deficient atoms such as Al or B.

The anthracene derrivative is the host material in a layer that includes one or more light-emitting materials. In addition to the anthracene host material, there may be one or more co-hosts present in the layer.

In one embodiment, a co-host is present that is a hole-transporting material. For example the co-host may be a tertiary amine or a mixture of such compounds. Examples of useful hole-transporting co-host materials are 4,4′-bis[N-(1-naphthyl)-N-phenylamino]biphenyl (NPB), and 4,4′-bis[N-(1-naphthyl)-N-(2-naphthyl)amino]biphenyl (TNB).

In another embodiment, a co-host that is an electron-transporting material is present. Metal complexes of 8-hydroxyquinoline and similar derivatives, also known as metal-chelated oxinoid compounds, constitute a class of useful co-host compounds. A useful example of electron-transporting co-host material is tris(8-quinolinolato)aluminum(III) (AlQ).

When present, the co-host is often at a level of 1-50% of the layer, frequently at 1-20% of the layer, and commonly at a level of 5-15% of the layer by volume.

The LEL includes a light-emitting material(s) which is desirably present in an amount of up to 15% of the light-emitting layer by volume, commonly 0.1-10% and more typically from 0.5-8.0% of the layer by volume.

An important relationship for choosing a light-emitting fluorescent material for use with a host is a comparison of the excited singlet-state energies of the host and the fluorescent material. It is highly desirable that the excited singlet-state energy of the light-emitting material be lower than that of the host material. The excited singlet-state energy is defined as the difference in energy between the emitting singlet state and the ground state. For non-emissive hosts, the lowest excited state of the same electronic spin as the ground state is considered the emitting state.

The layer may emit light ranging from blue to red depending on the nature of the light-emitting material. Blue light is generally defined as having a wavelength range in the visible region of the electromagnetic spectrum of 450-480 nm, blue-green 480-510 nm, green 510-550, green-yellow 550-570 nm, yellow 570-590 nm, orange 590-630 nm and red 630-700 nm, as defined by R. W. Hunt, The Reproduction of Colour in Photography, Printing & Television, 4^{th} Edition 1987, Fountain Press. Suitable combinations of these components produce white light.

Anthracene materials of Formula (1) may be especially useful hosts for blue or blue-green materials. Many materials that emit blue or blue-green light are known in the art and are contemplated for use in the practice of the present invention. Particularly useful classes of blue emitters include perylene and its derivatives such as a perylene nucleus bearing one or more substituents such as an alkyl group or an aryl group. A desirable perylene derivative for use as an emitting material is 2,5,8,11-tetra-t-butylperylene.

Another useful class of fluorescent materials includes blue or blue-green light emitting derivatives of distyrylarenes, such as distyrylbenzene and distyrylbiphenyl, including compounds described in U.S. Pat. No. 5,121,029. Among derivatives of distyrylarenes that provide blue or blue-green luminescence, particularly useful are those substituted with diarylamino groups, also known as distyrylamines. Examples include Formula (4a), listed below, wherein Ar₁, each Ar₂, and Ar₃ through Ar₈ are independently selected aryl or heteroaryl groups, which may contain additional fused rings and provided that two aryl or heteroaryl rings may be joined by ring fusion, m is 0 or 1. In one embodiment, Ar₁, each Ar₂, and Ar₃ through Ar₈ represent phenylene or phenyl groups.

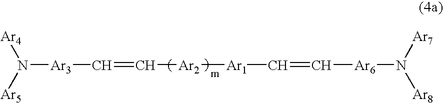

Illustrative examples of useful distyrylamines are blue or blue green emitters listed below.

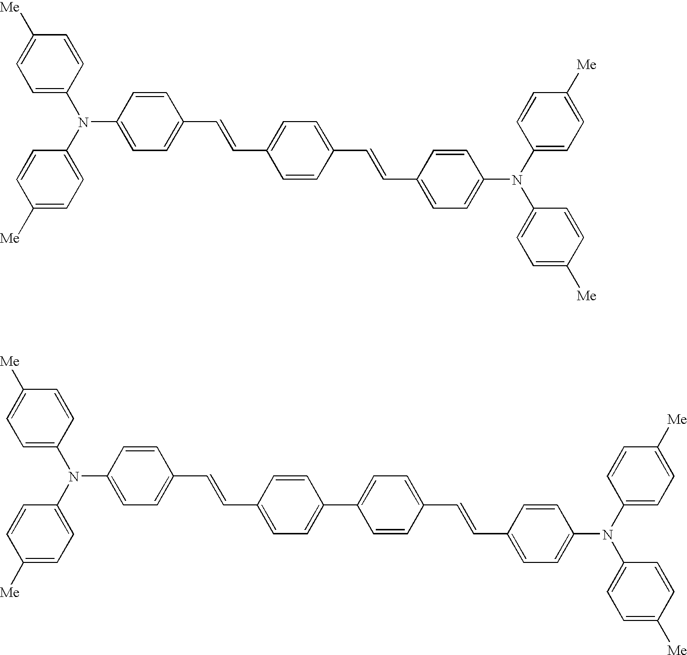

Commonly assigned Ser. No. 10/977,839, filed Oct. 29, 2004 entitled Organic Element for Electroluminescent Devices by Margaret J. Helber, et al., which is incorporated herein by reference, describes additional useful blue and blue-green light-emitting materials.

In one embodiment the light-emitting material is represented by Formula (4b).

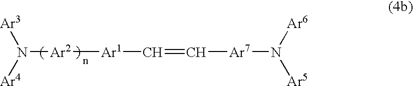

In Formula (4b), Ar¹ through Ar⁶ are independently selected aryl groups and may each represent phenyl groups, fused aromatic rings such as naphthyl, anthranyl or phenanthryl, heterocyclic aromatic rings wherein one or more carbon atoms have replaced by nitrogen, oxygen or sulfur, and monovalently linked aromatic rings such as biphenyl, and Ar¹ through Ar⁶ may be unsubstituted or further substituted in those ring positions bearing hydrogens. Additionally Ar³ and Ar⁴ may be joined directly or through additional atoms to form a carbocyclic or heterocyclic ring. Ar⁵ and Ar⁶ may be joined directly or through additional atoms to form a carbocyclic or heterocyclic ring. Ar⁷ represents a phenylene group, a fused ring aromatic carbocyclic group or a heterocyclic group. Ar⁷ may be unsubstituted or further substituted in those ring positions bearing hydrogens. In the Formula, n is 1, 2, or 3. Illustrative examples of useful materials are shown below.

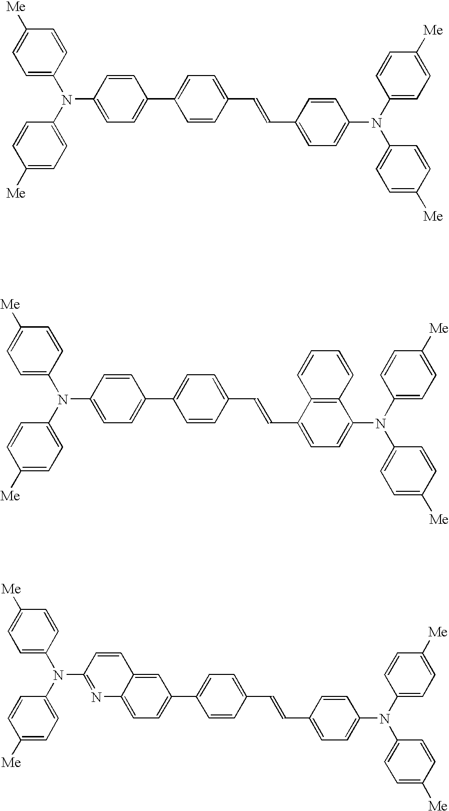

Another useful class of emitters comprise a boron atom. Desirable light-emitting materials that contain boron include those described in US 2003/0198829, US 2003/0201415 and US 2005/0170204, which are incorporated herein by reference. Suitable light-emitting materials, including those that emit blue or blue-green light, are represented by the structure Formula (5).

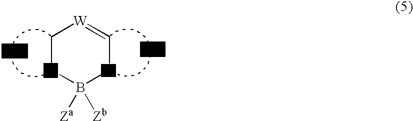

In Formula (5), Ar^{a} and Ar^{b} independently represent the atoms necessary to form a five or six-membered aromatic ring group, such as a pyridine group. Z^{a} and Z^{b} represent independently selected substituents, such as fluoro substituents. In Formula (5), w represents N or C-Y, wherein Y represents hydrogen or a substituent, such as an aromatic group, such as a phenyl group or a tolyl group, an alkyl group, such as a methyl group, a cyano substituent, or a trifluoromethyl substituent.

Illustrative examples of useful boron-containing fluorescent materials are listed below.

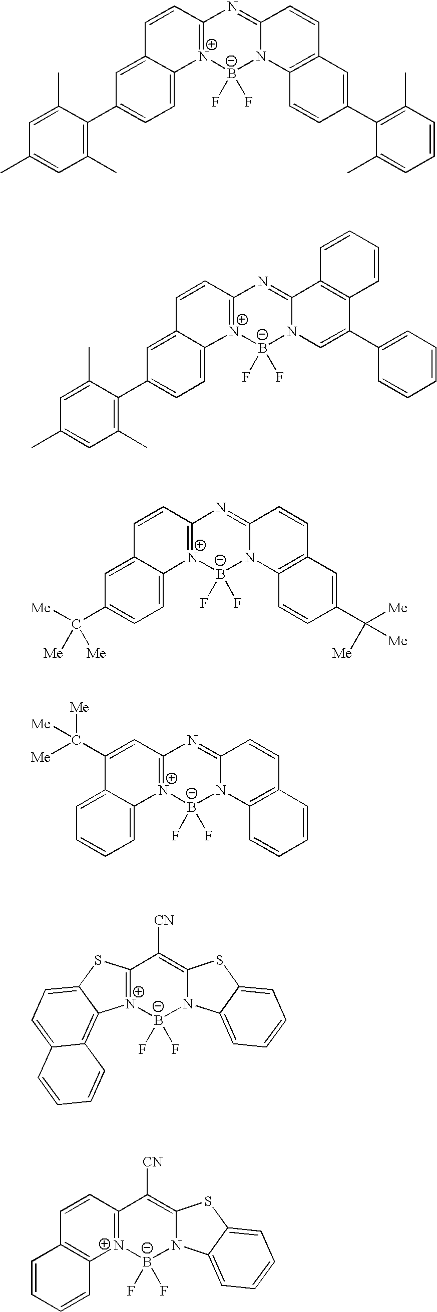

A particularly useful class of green light-emitting material includes quinacridone compounds. Useful quinacridones are described US 2004/0001969, U.S. Pat. No. 6,664,396, U.S. Pat. No. 5,593,788, and JP 09-13026. In one embodiment, the light-emitting material in the light-emitting layer is a quinacridone compound represented by Formula (6).

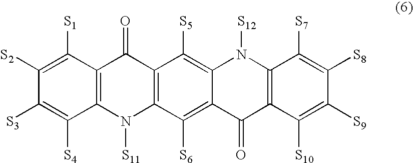

In Formula (6), s₁-s₁₀ independently represent hydrogen or an independently selected substituent, such as a phenyl group, a tolyl group, a halogen such as F, or an alkyl group, such as a methyl group. Adjacent substituents may combine to form rings, such as fused benzene ring groups.

In Formula (6), s₁₁ and S₁₂ independently represent an alkyl group or an aromatic group. In one suitable embodiment, s₁₁ and S₁₂ independently represent a phenyl ring group, such as a phenyl ring or a tolyl ring.

Illustrative examples of useful quinacridone compounds are shown below.

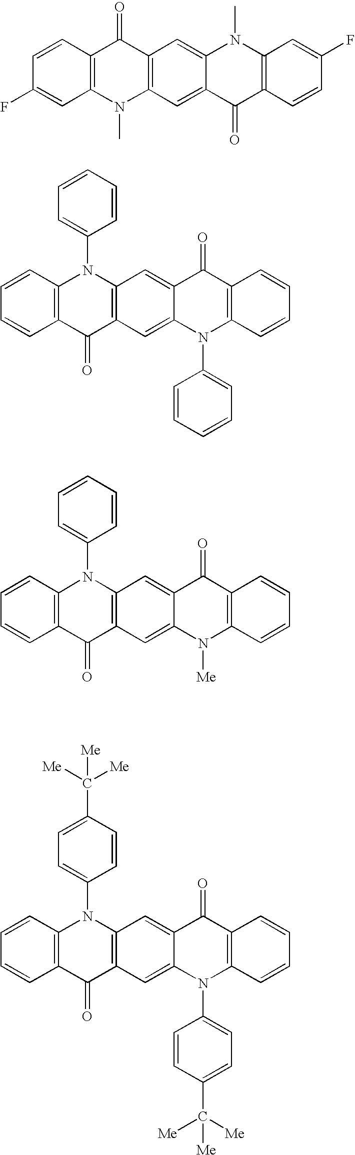

Another particularly useful class of green light-emitting materials includes coumarin compounds. For example, useful coumarins are described in Tang et al., U.S. Pat. No. 4,769,292 and U.S. Pat. No. 6,020,078. In one embodiment of the invention, the third material in the light-emitting layer is a coumarin represented by Formula (7).

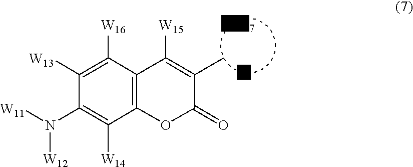

In Formula (7), W₁₁ and w₁₂ represent an independently selected substituent, such as an alkyl group or aryl group, provided w₁₁ and W₁₂ may combine with each other or with w₁₃ and W₁₄ to form rings. Desirably w₁₁ and w₁₂ represent independently selected alkyl groups, provided w₁₁ and W₁₂ may combine with each other or with w₁₃ and w₁₄ to form saturated rings. In Formula (7), w₁₃ -w₁₆ independently represent hydrogen or an independently selected substituent, such as phenyl ring group or a methyl group. Adjacent substituents may combine to form rings, such as fused benzene rings. In Formula (7), W₁₇ represents the atoms necessary to complete a heteroaromatic ring, such as a benzothiazole ring group. Illustrative examples of useful coumarin compounds are shown below.

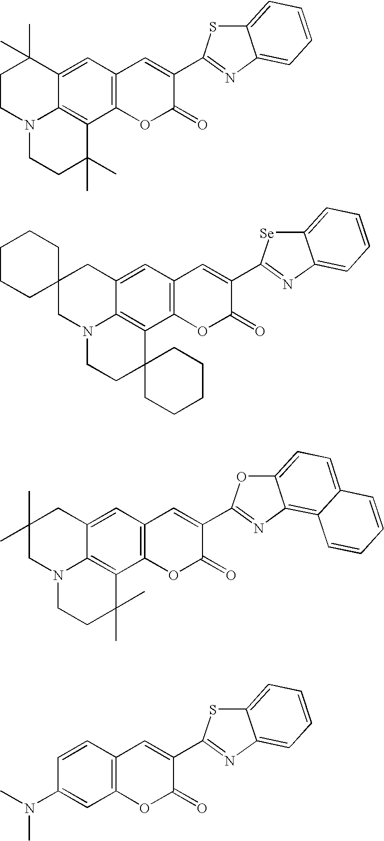

Examples of additional useful emitting materials include derivatives of anthracene, fluorene, periflanthene, and indenoperylene.

In one embodiment, one layer including an anthracene compound of Formula (1) emits blue or blue-green light and an additional layer emits yellow or red light and contains a rubrene derivative.

In another embodiment, when additional layers are present so that the emitted light is white, a filter capable of controlling the spectral components of the white light such as red, green and blue, can be placed over-lying the device to give a device useful for color display.

In another aspect of the invention, a useful device includes a further layer located between the light-emitting layer and the cathode. The further layer includes an electron-transporting material having at least 3 fused carbocyclic rings, such as an anthracene or tetracene nucleus. In one desirable embodiment the electron-transporting material includes an anthracene nucleus. Desirably the anthracene nucleus is substituted with aromatic groups in the 2-, 9-, and 10-positions. Examples of useful aromatic rings include naphthyl groups such as a 1-naphthyl group, a 2-naphthyl group, and biphenyl groups such as a 4-biphenyl group and a 3-biphenyl group. In another suitable embodiment, the electron-transporting material includes a tetracene nucleus such as rubrene or a derivative of rubrene.

Desirably there is an additional layer between the further layer and the cathode wherein the additional layer functions as a second electron-transporting layer or as an electron-injecting layer. In this embodiment, the additional layer includes a heterocyclic compound. Suitably, the heterocyclic compound includes a phenanthroline nucleus, such as 1,10-phenanthroline or a derivative thereof. In another embodiment, the heterocyclic compound includes a metal complex including an 8-quinolinolate nucleus. Especially desirable metals include aluminum and gallium. Examples of useful complexes are tris(8-quinolinolato)aluminum (III) (Alq), tris(8-quinolinolato)gallium (III) and similar materials.

General Device Architecture

The present invention can be employed in many OLED device configurations using small molecule materials, oligomeric materials, polymeric materials, or combinations thereof These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

There are numerous configurations of the organic layers wherein the present invention can be successfully practiced. The essential requirements of an OLED are an anode, a cathode, and an organic light-emitting layer located between the anode and cathode. Additional layers may be employed as more fully described hereafter.

A typical structure, especially useful for of a small molecule device, is shown in the Figure and is comprised of a substrate 101, an anode 103, a hole-injecting layer 105, a hole-transporting layer 107, a light-emitting layer 109, an electron-transporting layer 111, an electron-injecting layer 112, and a cathode 113. These layers are described in detail below. Note that the substrate may alternatively be located adjacent to the cathode, or the substrate may actually constitute the anode or cathode. The organic layers between the anode and cathode are conveniently referred to as the organic EL element. Also, the total combined thickness of the organic layers is desirably less than 500 nm.

The anode and cathode of the OLED are connected to a voltage/current source 150 through electrical conductors 160. The OLED is operated by applying a potential between the anode and cathode such that the anode is at a more positive potential than the cathode. Holes are injected into the organic EL element from the anode and electrons are injected into the organic EL element at the cathode. Enhanced device stability can sometimes be achieved when the OLED is operated in an AC mode where, for some time period in the cycle, the potential bias is reversed and no current flows. An example of an AC driven OLED is described in U.S. Pat. No. 5,552,678.

Substrate

The OLED device of this invention is typically provided over a supporting substrate 101 where either the cathode or anode can be in contact with the substrate. The substrate can be a complex structure comprising multiple layers of materials. This is typically the case for active matrix substrates wherein TFTs are provided below the OLED layers. It is still necessary that the substrate, at least in the emissive pixilated areas, be comprised of largely transparent materials. The electrode in contact with the substrate is conveniently referred to as the bottom electrode. Conventionally, the bottom electrode is the anode, but this invention is not limited to that configuration. The substrate can either be light transmissive or opaque, depending on the intended direction of light emission. The light transmissive property is desirable for viewing the EL emission through the substrate. Transparent glass or plastic is commonly employed in such cases. For applications where the EL emission is viewed through the top electrode, the transmissive characteristic of the bottom support can be light transmissive, light absorbing or light reflective. Substrates for use in this case include, but are not limited to, glass, plastic, semiconductor materials, silicon, ceramics, and circuit board materials. It is necessary to provide in these device configurations a light-transparent top electrode.

Anode

When the desired electroluminescent light emission (EL) is viewed through anode, the anode should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode, the transmissive characteristics of the anode are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize shorts or enhance reflectivity.

Hole-Injecting Layer (HIL)

While not always necessary, it is often useful that a hole-injecting layer 105 be provided between anode 103 and hole-transporting layer 107. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, plasma-deposited fluorocarbon polymers as described in U.S. Pat. No. 6,208,075, and some aromatic amines, for example, m-MTDATA (4,4′,4″-tris[(3-methylphenyl)phenylamino]triphenylamine). Alternative hole-injecting materials reportedly useful in organic EL devices are described in EP 0891121 and EP 1029909.

Additional useful hole-injecting materials are described in U.S. Pat. No. 6,720,573. For example, the material below may be useful for such purposes. 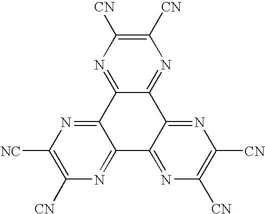
Hole-Transporting Layer (HTL)

The hole-transporting layer 107 of the organic EL device contains at least one hole-transporting compound, such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520.

A more preferred class of aromatic tertiary amines are those which include at least two aromatic tertiary amine moieties as described in US 4,720,432 and U.S. Pat. No. 5,061,569. Such compounds include those represented by structural Formula (A).

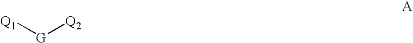

In Formula (A), Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring structure, e.g., a naphthalene. When G is an aryl group, it is conveniently a phenylene, biphenylene, or naphthalenediyl moiety.

A useful class of triarylamines satisfying structural Formula (A) and containing two triarylamine moieties is represented by structural Formula (B).

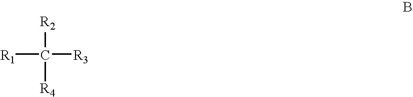

In Formula (B), R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural Formula (C).

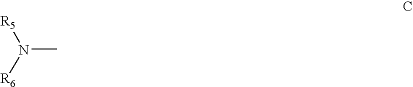

In Formula (C), R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by Formula (C), linked through an arylene group. Useful tetraaryldiamines include those represented by Formula (D).

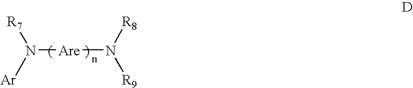

In Formula (D), each Are is an independently selected arylene group, such as a phenylene, naphthylenediyl or anthracenediyl moiety and n is an integer of from 1 to 4. Ar, R₇, R₈, and R₉ are independently selected aryl groups. In a typical embodiment, at least one of Ar, R₇, R₈, and Rg is a polycyclic fused ring structure, e.g., a naphthalene.

The various alkyl, alkylene, aryl, and arylene moieties of the foregoing structural Formulae (A), (B), (C), (D), can each in turn be substituted. Typical substituents include alkyl groups, alkoxy groups, aryl groups, aryloxy groups, benzo and halogen such as fluoride. The various alkyl and alkylene moieties typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene moieties are usually phenyl and phenylene moieties.

The hole-transporting layer can be formed of a single or a mixture of aromatic tertiary amine compounds. Specifically, one may employ a triarylamine, such as a triarylamine satisfying the Formula (B), in combination with a tetraaryldiamine, such as indicated by Formula (D). When a triarylamine is employed in combination with a tetraaryldiamine, the latter is positioned as a layer interposed between the triarylamine and the electron injecting and transporting layer. Illustrative of useful aromatic tertiary amines are the following:

1,1-Bis(4-di-p-tolylaminophenyl)cyclohexane (TAPC)

1,1-Bis(4-di-p-tolylaminophenyl)-4-phenylcyclohexane

4,4′-Bis(diphenylamino)quadriphenyl

Bis(4-dimethylamino-2-methylphenyl)-phenylmethane

N,N,N-Tri(p-tolyl)amine

4-(di-p-tolylamino)-4′-[4(di-p-tolylamino)-styryl]stilbene

N,N,N′,N′-Tetra-p-tolyl-4-4′-diaminobiphenyl

N,N,N′,N′-Tetraphenyl-4,4′-diaminobiphenyl

N,N,N′,N′-tetra-1-naphthyl-4,4′-diaminobiphenyl

N,N,N′,N′-tetra-2-naphthyl-4,4′-diaminobiphenyl

N-Phenylcarbazole

4,4′-Bis[N-(1-naphthyl)-N-phenylamino]biphenyl

4,4′-Bis[N-(1-naphthyl)-N-(2-naphthyl)amino]biphenyl

4,4″-Bis[N-(1-naphthyl)-N-phenylamino]p-terphenyl

4,4′-Bis[N-(2-naphthyl)-N-phenylamino]biphenyl

4,4′-Bis[N-(3-acenaphthenyl)-N-phenylamino]biphenyl

1,5-Bis[N-(1-naphthyl)-N-phenylamino]naphthalene

4,4′-Bis[N-(9-anthryl)-N-phenylamino]biphenyl

4,4″-Bis[N-(1-anthryl)-N-phenylamino]-p-terphenyl

4,4′-Bis[N-(2-phenanthryl)-N-phenylamino]biphenyl

4,4′-Bis[N-(8-fluoranthenyl)-N-phenylamino]biphenyl

4,4′-Bis[N-(2-pyrenyl)-N-phenylamino]biphenyl

4,4′-Bis[N-(2-naphthacenyl)-N-phenylamino]biphenyl

4,4′-Bis[N-(2-perylenyl)-N-phenylamino]biphenyl

4,4′-Bis[N-(1-coronenyl)-N-phenylamino]biphenyl

2,6-Bis(di-p-tolylamino)naphthalene

2,6-Bis[di-(1-naphthyl)amino]naphthalene

2,6-Bis[N-(1-naphthyl)-N-(2-naphthyl)amino]naphthalene

N,N,N′,N′-Tetra(2-naphthyl)-4,4″-diamino-p-terphenyl

4,4′-Bis{N-phenyl-N-[4-(1-naphthyl)-phenyl]amino}biphenyl

4,4′-Bis[N-phenyl-N-(2-pyrenyl)amino]biphenyl

2,6-Bis[N,N-di(2-naphthyl)amine]fluorene

1,5-Bis[N-(1-naphthyl)-N-phenylamino]naphthalene

4,4′,4″-tris[(3-methylphenyl)phenylamino]triphenylamine.

Another class of useful hole-transporting materials includes polycyclic aromatic compounds as described in EP 1,009,041. Tertiary aromatic amines with more than two amine groups may be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-Emitting Layer (LEL)

A useful light-emitting layer (LEL) has been described previously. In some embodiments a useful device includes more than one LEL. Additional light-emitting layers may include a luminescent fluorescent or phosphorescent material. The light-emitting layer can be comprised of a single material, but more commonly consists of a host material doped with a guest emitting material or materials where light emission comes primarily from the emitting materials and can be of any color. The host materials in the light-emitting layer can be an electron-transporting material, as defined below, a hole-transporting material, as defined above, or another material or combination of materials that support hole-electron recombination. The emitting material is usually chosen from highly fluorescent dyes and phosphorescent compounds, e.g., transition metal complexes as described in WO 98/55561, WO 00/18851, WO 00/57676, and WO 00/70655. Emitting materials are typically incorporated at 0.01 to 10% by weight of the host material.

The host and emitting materials can be small non-polymeric molecules or polymeric materials such as polyfluorenes and polyvinylarylenes (e.g., poly(p-phenylenevinylene), PPV). In the case of polymers, small molecule emitting materials can be molecularly dispersed into a polymeric host, or the emitting materials can be added by copolymerizing a minor constituent into a host polymer.

An important relationship for choosing an emitting material is a comparison of the bandgap potential which is defined as the energy difference between the highest occupied molecular orbital and the lowest unoccupied molecular orbital of the molecule. For efficient energy transfer from the host to the emitting material, a necessary condition is that the band gap of the dopant is smaller than that of the host material. For phosphorescent emitters it is also important that the host triplet energy level of the host be high enough to enable energy transfer from host to emitting material.

Host and emitting materials known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

Metal complexes of 8-hydroxyquinoline and similar derivatives (Formula E) constitute one class of useful host compounds capable of supporting electroluminescence, and are particularly suitable for light emission of wavelengths longer than 500 nm, e.g., green, yellow, orange, and red.

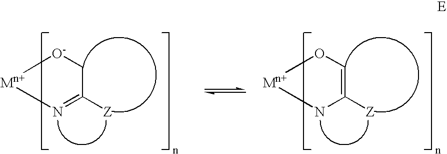

In Formula (E), M represents a metal; n is an integer of from 1 to 4; and Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; an earth metal, such aluminum or gallium, or a transition metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
CO-1: Aluminum trisoxine [alias, tris(8-quinolinolato)aluminum(III); Alq]
CO-2: Magnesium bisoxine [alias, bis(8-quinolinolato)magnesium(II)]
CO-3: Bis[benzo{f}-8-quinolinolato]zinc (II)
CO-4: Bis(2-methyl-8-quinolinolato)aluminum(III)-μ-oxo-bis(2-methyl-8-quinolinolato) aluminum(III)
CO-5: Indium trisoxine[alias, tris(8-quinolinolato)indium]
CO-6: Aluminum tris(5-methyloxine) [alias, tris(5-methyl-8-quinolinolato) aluminum(III)]
CO-7: Lithium oxine[alias, (8-quinolinolato)lithium(I)]
CO-8: Gallium oxine[alias, tris(8-quinolinolato)gallium(III)]
CO-9: Zirconium oxine[alias, tetra(8-quinolinolato)zirconium(IV)].

Derivatives of anthracene (Formula F) constitute one class of useful host materials capable of supporting electroluminescence, and are particularly suitable for light emission of wavelengths longer than 400 nm, e.g., blue, green, yellow, orange or red. Asymmetric anthracene derivatives as disclosed in U.S. Pat. No. 6,465,115 and WO 2004/018587 are also useful hosts.

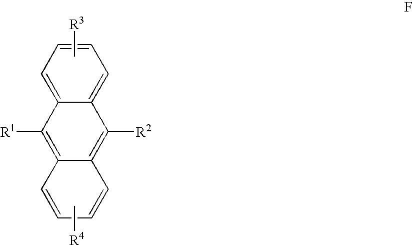

In Formula (F), R¹ and R² represent independently selected aryl groups, such as naphthyl, phenyl, biphenyl, triphenyl, anthracene. R³ and R⁴ represent one or more substituents on each ring where each substituent is individually selected from the following groups:
Group 1: hydrogen, or alkyl of from 1 to 24 carbon atoms;
Group 2: aryl or substituted aryl of from 5 to 20 carbon atoms;
Group 3: carbon atoms from 4 to 24 necessary to complete a fused aromatic ring of anthracenyl; pyrenyl, or perylenyl;

Group 4: heteroaryl or substituted heteroaryl of from 5 to 24 carbon atoms as necessary to complete a fused heteroaromatic ring of furyl, thienyl, pyridyl, quinolinyl or other heterocyclic systems;
Group 5: alkoxylamino, alkylamino, or arylamino of from 1 to 24 carbon atoms; and
Group 6: fluorine or cyano.

A useful class of anthracenes are derivatives of 9,10-di-(2-naphthyl)anthracene (Formula G).

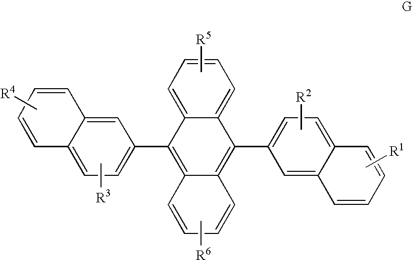

In Formula (G), R¹, R², R³, R⁴, R⁵, and R⁶ represent one or more substituents on each ring where each substituent is individually selected from the following groups:
Group 1: hydrogen, or alkyl of from 1 to 24 carbon atoms;
Group 2: aryl or substituted aryl of from 5 to 20 carbon atoms;
Group 3: carbon atoms from 4 to 24 necessary to complete a fused aromatic ring of anthracenyl; pyrenyl, or perylenyl;
Group 4: heteroaryl or substituted heteroaryl of from 5 to 24 carbon atoms as necessary to complete a fused heteroaromatic ring of furyl, thienyl, pyridyl, quinolinyl or other heterocyclic systems;
Group 5: alkoxylamino, alkylamino, or arylamino of from 1 to 24 carbon atoms; and
Group 6: fluorine or cyano.

Illustrative examples of anthracene materials for use in a light-emitting layer include: 2-(4-methylphenyl)-9,10-di-(2-naphthyl)-anthracene; 9-(2-naphthyl)-10-(1,1′-biphenyl)-anthracene; 9,10-bis[4-(2,2-diphenylethenyl)phenyl]-anthracene, as well as the following listed compounds.

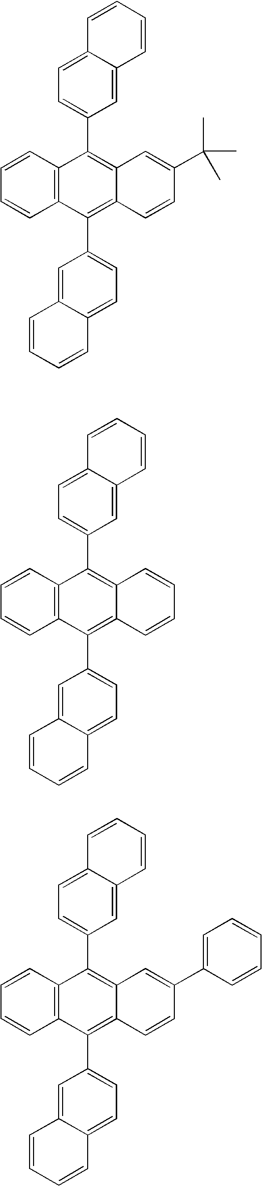

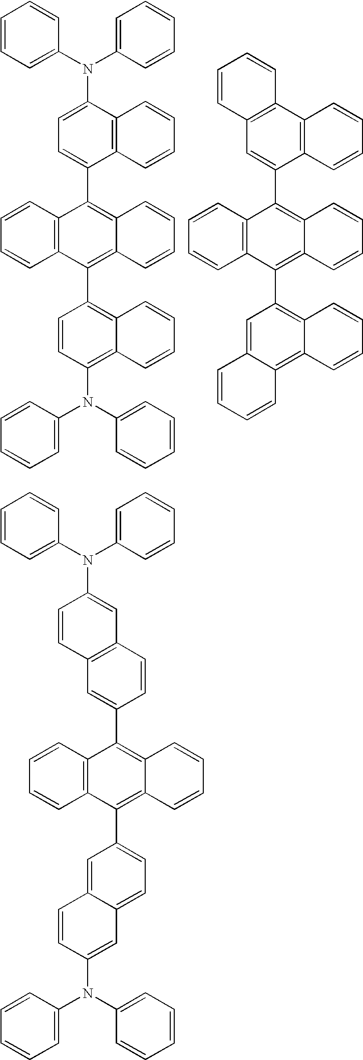

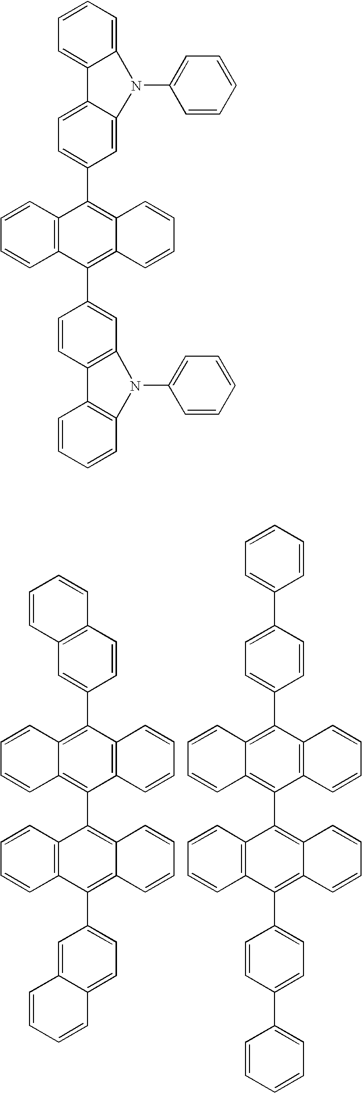

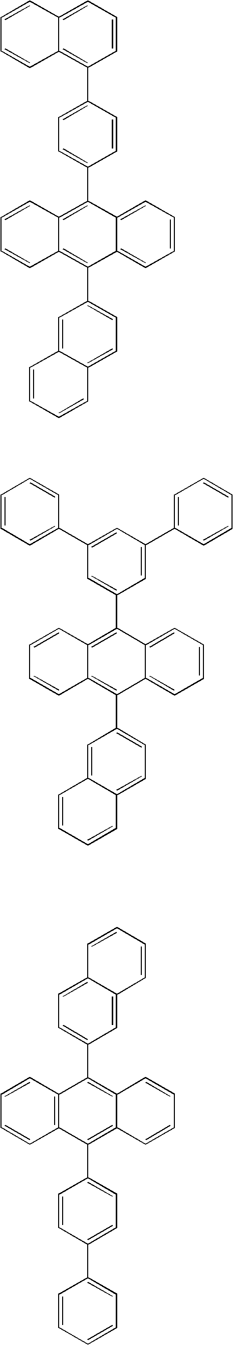

Benzazole derivatives (Formula H) constitute another class of useful host materials capable of supporting electroluminescence, and are particularly suitable for light emission of wavelengths longer than 400 nm, e.g., blue, green, yellow, orange or red.

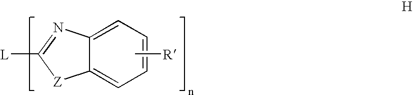

In Formula H, n is an integer of 3 to 8; Z is O, NR or S; and R and R′ are individually hydrogen; alkyl of from 1 to 24 carbon atoms, for example, propyl, t-butyl, heptyl, and the like; aryl or hetero-atom substituted aryl of from 5 to 20 carbon atoms for example phenyl and naphthyl, furyl, thienyl, pyridyl, quinolinyl and other heterocyclic systems; or halo such as chloro, fluoro; or atoms necessary to complete a fused aromatic ring. L is a linkage unit consisting of alkyl, aryl, substituted alkyl, or substituted aryl, which conjugately or unconjugately connects the multiple benzazoles together. An example of a useful benzazole is 2, 2′, 2″-(1,3,5-phenylene)tris[1-phenyl-1H-benzimidazole].

Distyrylarylene derivatives are also useful hosts, as described in U.S. Pat. No. 5,121,029. Carbazole derivatives are particularly useful hosts for phosphorescent emitters.

Useful fluorescent emitting materials include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, and carbostyryl compounds.

Examples of useful phosphorescent materials are reported in WO 00/57676, WO 00/70655, WO 01/41512, WO 02/15645, US 2003/0017361, WO 01/93642, WO 01/39234, U.S. Pat. No. 6,458,475, WO 02/071813, U.S. Pat. No. 6,573,651, US 2002/0197511, WO 02/074015, U.S. Pat. No. 6,451,455, US 2003/0072964, US 2003/0068528, U.S. Pat. No. 6,413,656, U.S. Pat. No. 6,515,298, U.S. Pat. No. 6,451,415, U.S. Pat. No. 6,097,147, US 2003/0124381, US 2003/0059646, US 2003/0054198, EP 1 239 526, EP 1 238 981, EP 1 244 155, US 2002/0100906, US 2003/0068526, US 2003/0068535, JP 2003073387, JP 2003073388, US 2003/0141809, US 2003/0040627, JP 2003059667, JP 2003073665, and US 2002/0121638.

Illustrative examples of useful fluorescent and phosphorescent emitting materials include, but are not limited to, the following compounds.

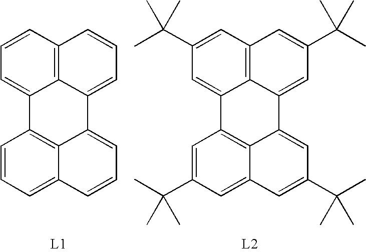

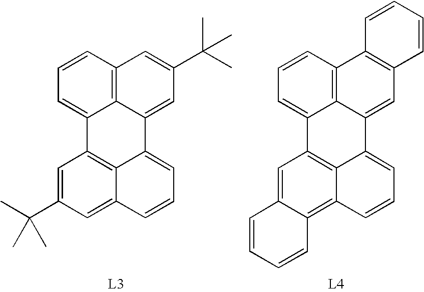

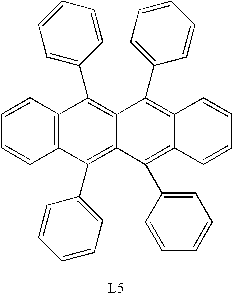

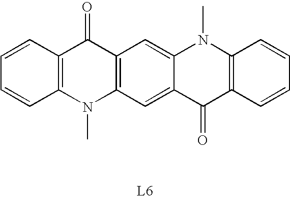

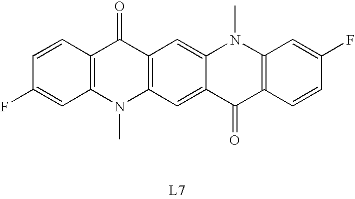

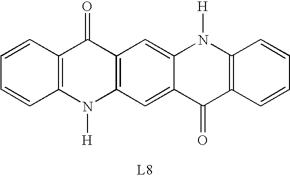

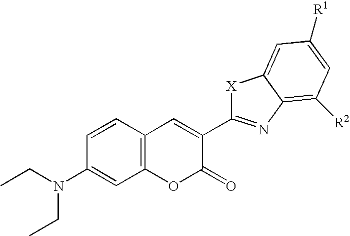

| X | R1 | R2 | |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |

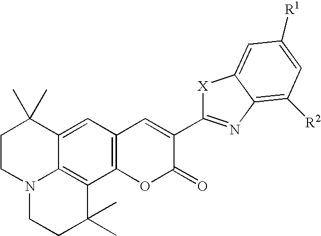

| | | | |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyl | t-butyl |

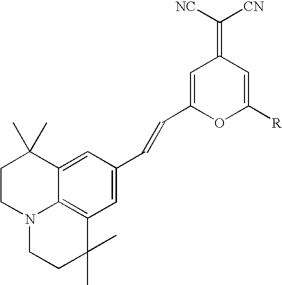

R

| | |
|---|---|
| L37 | phenyl |
| L38 | methyl |
| L39 | t-butyl |
| L40 | mesityl |

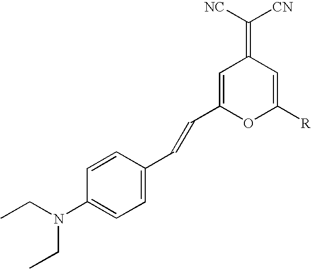

| | |
|---|---|
| L41 | phenyl |
| L42 | methyl |
| L43 | t-butyl |
| L44 | mesityl |

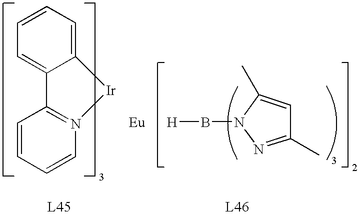

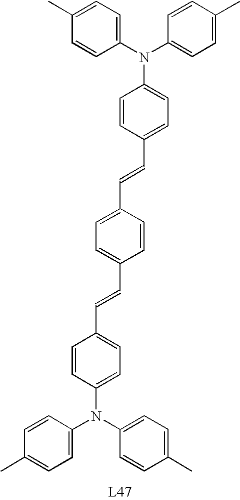

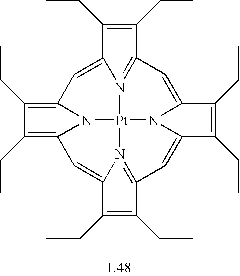

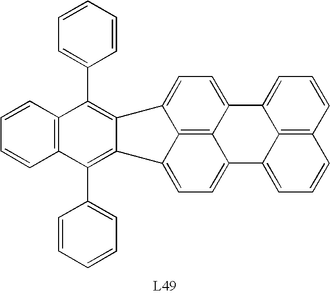

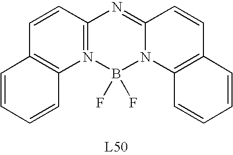

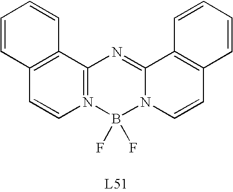

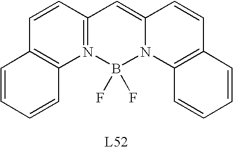

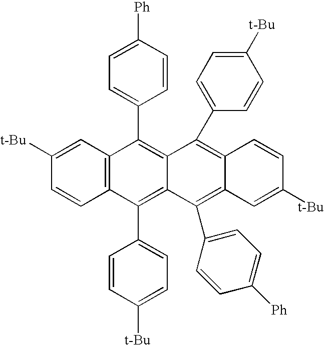

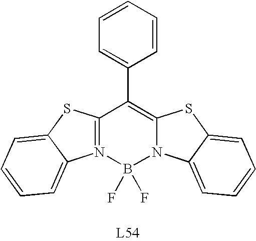

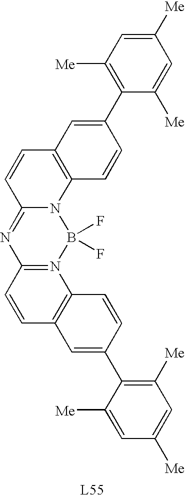

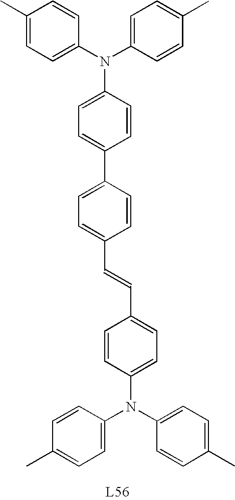

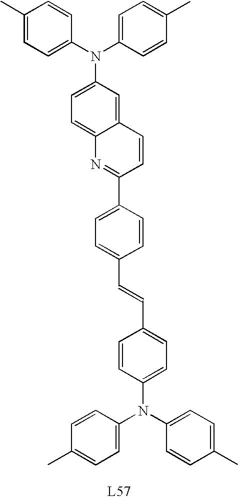

Electron-Transporting Layer (ETL)

Preferred thin film-forming materials for use in forming electron-transporting layer of the organic EL devices of this invention include metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural Formula (E), previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural Formula (H) are also useful electron transporting materials. Triazines are also known to be useful as electron transporting materials. Further useful materials are silacyclopentadiene derivatives described in EP 1,480,280; EP 1,478,032; and EP 1,469,533. Substituted 1,10-phenanthroline compounds such as are disclosed in JP2003-115387; JP2004-311184; JP2001-267080; and WO2002-043449. Pyridine derivatives are described in JP2004-200162 as useful electron transporting materials.

A useful ETL, including a material having at least three fused rings, such as an anthracene nucleus, has been described previously. It is desirable to use an ETL of this nature adjacent to a second ETL that includes a heterocyclic compound. The second ETL is adjacent to the cathode or adjacent to an electron-injecting layer that is adjacent to the cathode. Examples of useful heterocyclic compounds that can be used in the second ETL include 1,10-phenanthroline and tris(8-quinolinolato)aluminum (III) (Alq).

Electron-Injecting Layer (EIL)

Electron-injecting layers, when present, include those described in is U.S. Pat. Nos. 5,608,287; 5,776,622; 5,776,623; 6,137,223; and 6,140,763, 6,914,269 the disclosures of which are incorporated herein by reference. An electron-injecting layer generally consists of a material having a work function less than 4.0 eV. A thin-film containing low work-function alkaline metals or alkaline earth metals, such as Li, Cs, Ca, Mg can be employed. In addition, an organic material doped with these low work-function metals can also be used effectively as the electron-injecting layer. Examples are Li- or Cs-doped Alq. In one suitable embodiment the electron-injecting layer includes LiF. In practice, the electron-injecting layer is often a thin layer deposited to a suitable thickness in a range of 0.1-3.0 nm.

Cathode

When light emission is viewed solely through the anode, the cathode used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One useful cathode material is comprised of a Mg:Ag alloy wherein the percentage of silver is in the range of 1 to 20%, as described in U.S. Pat. No. 4,885,221. Another suitable class of cathode materials includes bilayers comprising the cathode and a thin electron-injection layer (EIL) in contact with an organic layer (e.g., an electron transporting layer (ETL)) which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861; 5,059,862, and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. Mo. 6,172,459, EP 1 076 368, U.S. Pat. No. 6,278,236, and U.S. Pat. No. 6,284,3936. Cathode materials are typically deposited by any suitable method such as evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Other Useful Organic Layers and Device Architecture

In some instances, layers 109 and 111 can optionally be collapsed into a single layer that serves the function of supporting both light emission and electron transportation. It also known in the art that emitting materials may be included in the hole-transporting layer, which may serve as a host. Multiple materials may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1 187 235, US 20020025419, EP 1 182 244, U.S. Pat. No. 5,683,823, U.S. Pat. No. 5,503,910, U.S. Pat. No. 5,405,709, and US 5,283,182 and may be equipped with a suitable filter arrangement to produce a color emission.

Additional layers such as electron or hole-blocking layers as taught in the art may be employed in devices of this invention. Hole-blocking layers may be used between the light emitting layer and the electron transporting layer. Electron-blocking layers may be used between the hole-transporting layer and the light emitting layer. These layers are commonly used to improve the efficiency of emission, for example, as in US 20020015859.

This invention may be used in so-called stacked device architecture, for example, as taught in U.S. Pat. No. 5,703,436 and U.S. Pat. No. 6,337,492.

Deposition of Organic Layers

The organic materials mentioned above are suitably deposited by any means suitable for the form of the organic materials. In the case of small molecules, they are conveniently deposited through sublimation, but can be deposited by other means such as from a solvent with an optional binder to improve film formation. If the material is a polymer, solvent deposition is usually preferred. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,688,551, U.S. Pat. No. 5,851,709 and U.S. Pat. No. 6,066,357) and inkjet method (U.S. Pat. No. 6,066,357).

One preferred method for depositing the materials of the present invention is described in US 2004/0255857 and U.S. Ser. No. 10/945,941 where different source evaporators are used to evaporate each of the materials of the present invention. A second preferred method involves the use of flash evaporation where materials are metered along a material feed path in which the material feed path is temperature controlled. Such a preferred method is described in the following co-assigned patent applications: U.S. Ser. No. 10/784,585; U.S. Ser. No. 10/805,980; U.S. Ser. No. 10/945,940; U.S. Ser. No. 10/945,941; U.S. Ser. No. 11/050,924; and U.S. Ser. No. 11/050,934. Using this second method, each material may be evaporated using different source evaporators or the solid materials may be mixed prior to evaporation using the same source evaporator.

Encapsulation

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization

OLED devices of this invention can employ various well-known optical effects in order to enhance its properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters over the display. Filters, polarizers, and anti-glare or anti-reflection coatings may be specifically provided over the cover or as part of the cover.

Embodiments of the invention may provide advantageous features such as higher luminous yield, lower drive voltage, and higher power efficiency, longer operating lifetimes or ease of manufacture. Embodiments of devices useful in the invention can provide a wide range of hues including those useful in the emission of white light (directly or through filters to provide multicolor displays). Embodiments of the invention can also provide an area lighting device.

The invention and its advantages are further illustrated by the specific examples that follow. The term “percentage” or “percent” and the symbol “%” indicate the volume percent (or a thickness ratio as measured on a thin film thickness monitor) of a particular first or second compound of the total material in the layer of the invention and other components of the devices. If more than one second compound is present, the total volume of the second compounds can also be expressed as a percentage of the total material in the layer of the invention.

### EXAMPLE 1

### Synthesis of inv-1 (Scheme II).

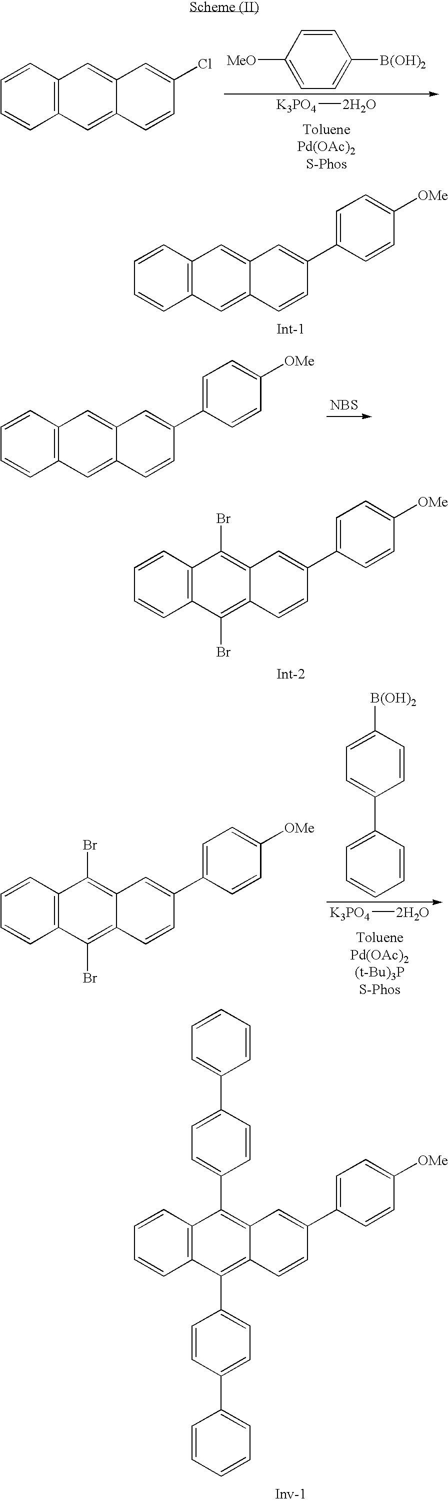 Preparation of 2-(p-methoxyphenyl)anthracene (Int-1).

A coupling catalyst was prepared by combining 2-chloroanthracene (415 mg, 2 mmol), palladium diacetate (224 mg, 1 mmol) and Sphos (2-(2′,6′-dimethoxybiphenyl)dicyclohexylphosphine, 455 mg, 1.1 mmol) in 20 mL of toluene and stirring the mixture at 35-40° C. for 10 min. The catalyst was added to a mixture of 2-chloroanthracene (21.8 g, 103 mmol) and p-methoxyphenylboronic acid (18.0 g, 118 mmol) and potassium phosphate dihydrate (78.0 g, 340 mmol) in 280 mL of toluene. The reaction temperature was increased from 22° C. to 45° C. over 20 min. with stirring. The temperature was then increased to 55° C.-60° C. for an additional 3 h. An additional amount of catalyst was added (0.2 mol %, prepared in the same way as described above) and the mixture was heated for 2 h at 70° C. The reaction mixture was heated to 100° C. and 130 mL of heptane was added followed by 200 mL of water. The mixture was heated at 100° C. and slowly cooled to about 10° C. The crude product was isolated by filtration, washed with water (three 100 mL portions) and then methanol to afford 25.9 g (87% yield) of 2-(p-methoxyphenyl)anthracene after drying.

Preparation of 9,10-dibromo-2-(p-methoxyphenyl)anthracene (Int-2).

N-Bromosuccimide (2.2 eq.) and 2-(p-methoxyphenyl)anthracene (1.0 g, 14 mmol) were combined with 60 mL of 1,2-dichloroethane and stirred at room temperature for 18 h. The reaction mixture was filtered and the solid obtained was washed with 1,2-dichloroethane and then methanol and dried. The crude product was purified by refluxing it in 100 mL of ethanol. After cooling to room temperature, the solid was collected by filtration and dried to yield 3.12 g of 9,10-dibromo-2-(p-methoxyphenyl)anthracene that was 97% pure by high performance liquid chromatography (hplc) analysis.

Preparation of Inv-1

9,10-Dibromo-2-(p-methoxyphenyl)anthracene (2.2 g, 5 mmol) and 4-biphenylboronic acid (2.2 g, 11 mmol) and palladium diacetate (18 mg, 0.7 mol %) and tri-(t-butyl)phosphine (0.8 mol %, 0.09 mL of a 1M solution in toluene) were combined in 20 mL of toluene with stirring. Potassium phosphate dihydrate (17.0 g, 30 mmol) was added and the mixture was stirred at ambient temperature for 1 h and at 65° C. for 1 h. Water was added and the product was isolated to afford 2.66 g (90% yield) of Inv-I that was 99% pure by hplc analysis.

### EXAMPLE 2

### Electrochemical Redox Potentials.

Electrochemical redox potentials were determined experimentally by the following electrochemical methods. A Model CH1660 electrochemical analyzer (CH Instruments, Inc., Austin, Tex.) was employed to carry out the electrochemical measurements. Cyclic voltammetry (CV) and Osteryoung square-wave voltammetry (SWV) were used to characterize the redox properties of the compounds of interest. A glassy carbon (GC) disk electrode (A=0.071 cm²) was used as working electrode. The GC electrode was polished with 0.05 μm alumina slurry, followed by sonication cleaning in Milli-Q deionized water twice and rinsed with acetone in between water cleaning. The electrode was finally cleaned and activated by electrochemical treatment prior to use. A platinum wire served as counter electrode and a saturated calomel electrode (SCE) was used as a quasi-reference electrode to complete a standard 3-electrode electrochemical cell. Ferrocene (Fc) was used as an internal standard (E_{Fc}=0.50 V vs. SCE in 1:1 acetonitrile/toluene, 0.1 M TBAF). A mixture of acetonitrile and toluene (50%/o/50% v/v, or 1:1) was used as the organic solvent system. The supporting electrolyte, tetrabutylammonium tetraflouroborate (TBAF) was recrystallized twice in isopropanol and dried under vacuum. All solvents used were low water grade (<20 ppm water). The testing solution was purged with high purity nitrogen gas for approximately 5 minutes to remove oxygen and a nitrogen blanket was kept on the top of the solution during the course of the experiments. All measurements were performed at ambient temperature of 25±1° C. The oxidation and reduction potentials were determined either by averaging the anodic peak potential (Ep,a) and cathodic peak potential (Ep,c) for reversible or quasi-reversible electrode processes or on the basis of peak potentials (in SWV) for irreversible processes. Measured Eox vs. SCE values are listed in Table 1.

The oxidation potential of compounds of interest can also be estimated from molecular orbital calculations. Typical calculations are carried out by using the B3LYP method as implemented in the Gaussian 98 (Gaussian, Inc., Pittsburgh, Pa.) computer program. The basis set for use with the B3LYP method is defined as follows: MIDI! for all atoms for which MIDI! is defined, 6-31G* for all atoms defined in 6-31G* but not in MIDI!, and either the LACV3P or the LANL2DZ basis set and pseudopotential for atoms not defined in MIDI! or 6-31G*, with LACV3P being the preferred method. For any remaining atoms, any published basis set and pseudopotential may be used. MIDI!, 6-31G* and LANL2DZ are used as implemented in the Gaussian98 computer code and LACV3P is used as implemented in the Jaguar 4.1 (Schrodinger, Inc., Portland Oreg.) computer code. Calculations provide the energy level of the highest occupied molecular orbital (HOMO) and lowest unoccupied molecular orbital (LUMO) in Hartree units where 1 Hartree unit is 27.21 eV. An estimate of the compounds Eox vs. SCE value is obtained from the following equation:
Eox=−0.643(E_{H})−2.03 V.

The measured and calculated oxidation potentials of select compounds are listed in Table 1.

TABLE 1
Experimental and calculated oxidation potentials.

| | | | Measured |
|---|---|---|---|
| | | Calc. | Eox |
| Compd. | Structure | Eox | (vs SCE) |
| Inv-1 | 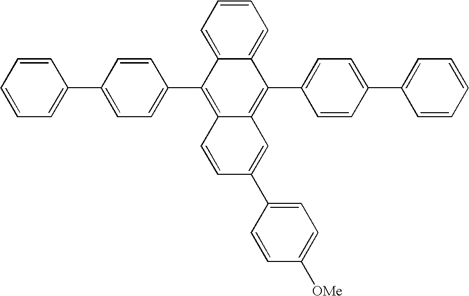 | 1.22 | 1.24 |
| Inv-2 | 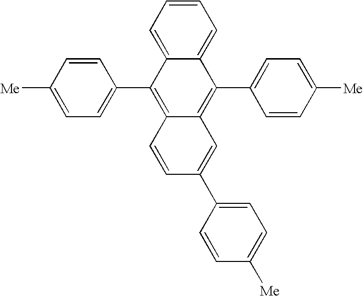 | 1.23 | 1.24 |
| Inv-3 | 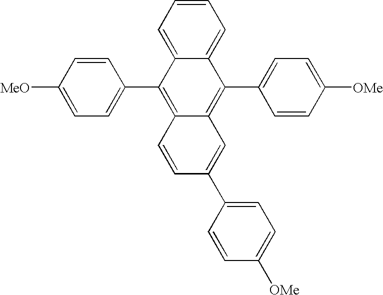 | 1.13 | — |
| Inv-4 | 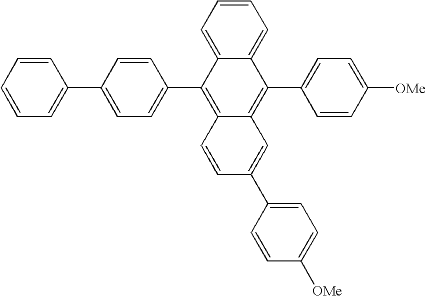 | 1.17 | — |
| Inv-5 | 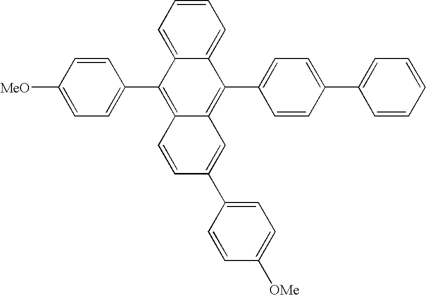 | 1.18 | — |
| Inv-6 | 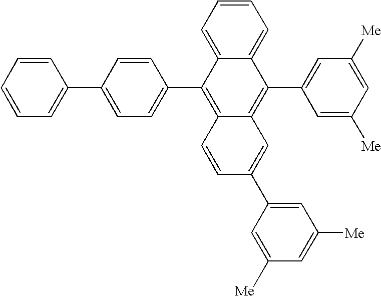 | 1.24 | — |
| Inv-25 | 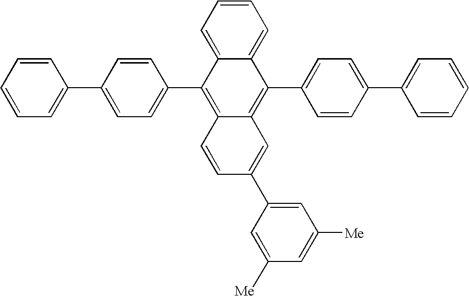 | 1.27 | — |
| Inv-26 | 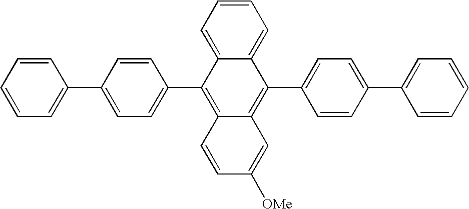 | 1.22 | — |
| Inv-27 | 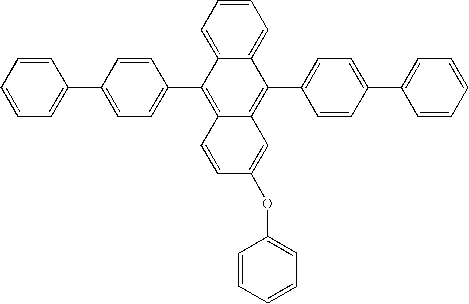 | 1.25 | — |
| Inv-28 | 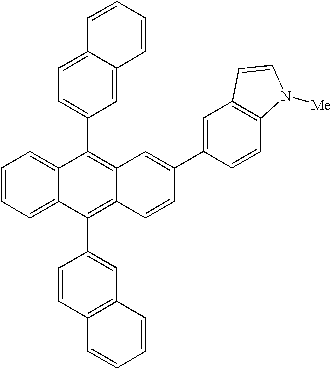 | 1.17 | — |
| Inv-28 | 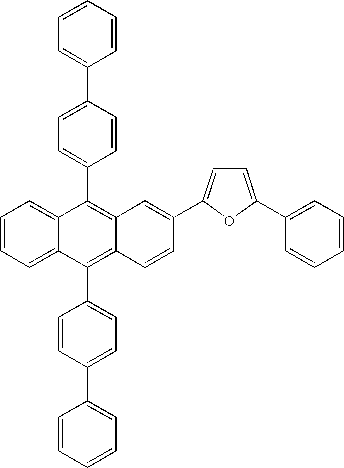 | 1.22 | — |
| C-1 | 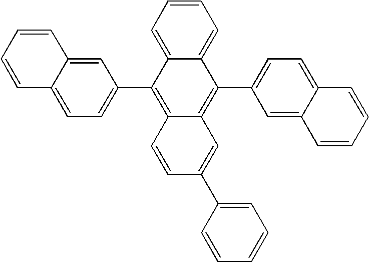 | 1.30 | 1.29 |
| C-2 | 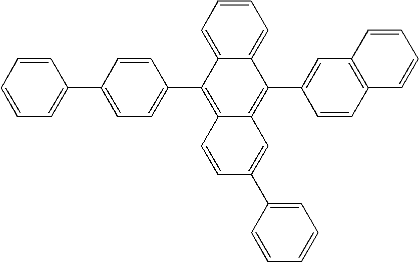 | 1.29 | — |
| C-3 | 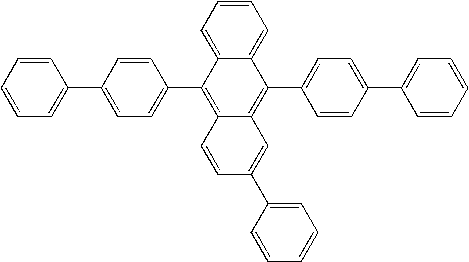 | 1.29 | — |
| C-4 | 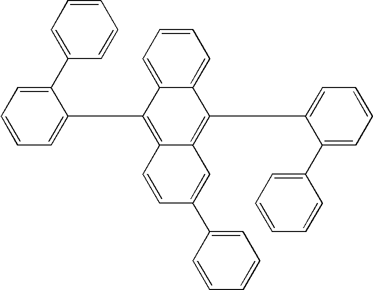 | 1.29 | — |
| C-5 | 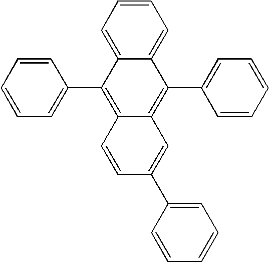 | 1.30 | — |
| C-6 | 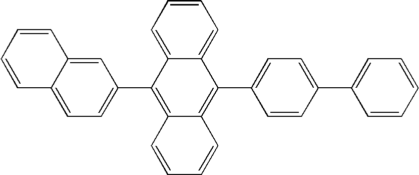 | 1.32 | 1.31 |
| C-7 | 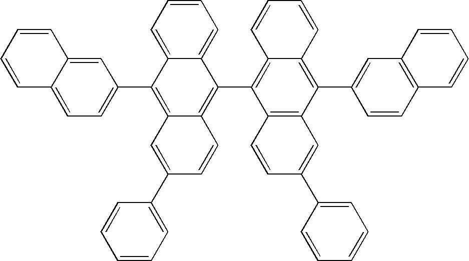 | 1.32 | 1.25 |
| C-8 | 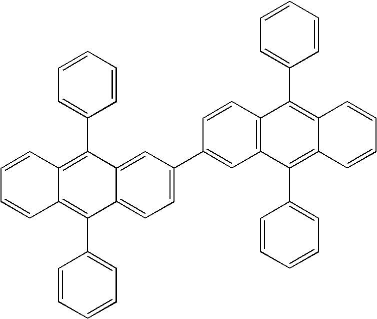 | 1.21 | 1.24 |
| C-9 | 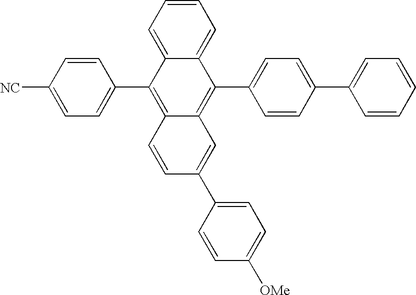 | 1.35 | — |

### EXAMPLE 3

### Fabrication of Device 1-1 through 1-4.

A series of EL devices (1-1 through 1-4) were constructed in the following manner.
1. A glass substrate coated with a 21.5 nm layer of indium-tin oxide (ITO), as the anode, was sequentially ultrasonicated in a commercial detergent, rinsed in deionized water, degreased in toluene vapor and exposed to oxygen plasma for about 1 min.
2. Over the ITO was deposited a 1 nm fluorocarbon (CFx) hole-injecting layer (HIL) by plasma-assisted deposition of CHF₃ as described in U.S. Pat. No. 6,208,075.
3. Next a layer of hole-transporting material 4,4′-Bis[N-(1-naphthyl)-N-phenylamino]biphenyl (NPB) was deposited to a thickness of 75 nm.
4. A light-emitting layer (LEL) at a thickness shown in Table 2a and corresponding to C-1 or Inv-1 (see Table 2a) and including light-emitting material, D-1, at a level of 0.75% of the layer by volume was then deposited.
5. An electron-transporting layer (ETL) of tris(8-quinolinolato)aluminum (III) (Alq), was vacuum-deposited over the LEL. The thickness of the ETL was adjusted (Table 2a) so that each device fabricated had the same overall device thickness.
6. 0.5 nm layer of lithium fluoride was vacuum deposited onto the ETL, followed by a 150 nm layer of aluminum, to form a cathode layer.

The above sequence completed the deposition of the EL device. The device was then hermetically packaged in a dry glove box for protection against ambient environment.

TABLE 2a

| | |
|---|---|
| | (C-1) |
| 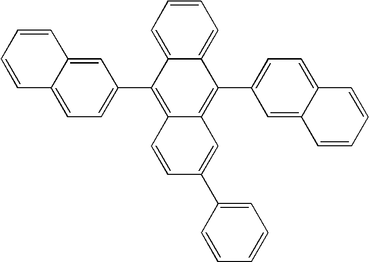 | |
| | (D-1) |
| 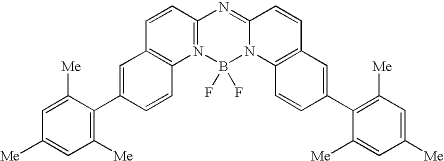 | |

The LEL and ETL for Devices 1-1 through 1-4.

| | | | LEL | Emitter | | ETL |
|---|---|---|---|---|---|---|
| | | LEL | Thick. | Level | ETL | Thick. |
| | Example | Host | (nm) | (%) | Material | (nm) |
| 1-1 | Comparative | C-1 | 20 | 0.75 | Alq | 35 |
| 1-2 | Inventive | Inv-1 | 20 | 0.75 | Alq | 35 |
| 1-3 | Inventive | Inv-1 | 30 | 0.75 | Alq | 25 |
| 1-4 | Inventive | Inv-1 | 40 | 0.75 | Alq | 15 |

The devices were tested for luminous efficiency and color at an operating current of 20 mA/cm² and the results are reported in Table 2b in the form of luminous yield (cd/A) and efficiency (w/A), where device efficiency is the radiant flux (in watts) produced by the device per amp of input current, where radiant flux is the light energy produced by the device per unit time. Light intensity is measured perpendicular to the device surface, and it is assumed that the angular profile is Lambertian. The color of light produced by the device is reported in 1931 CIE (Commission Internationale de L'Eclairage) coordinates. Drive voltage is reported in volts.

TABLE 2b
Evaluation results for Devices 1-1 through 1-4.

| | | | | Lum. | | |
|---|---|---|---|---|---|---|
| | | | | Yield | Eff. | Voltage |
| Device | Example | CIEx | CIEy | (cd/A) | (W/A) | (V) |
| 1-1 | Comparative | 0.162 | 0.169 | 2.45 | 0.046 | 7.06 |
| 1-2 | Inventive | 0.177 | 0.207 | 2.68 | 0.042 | 6.12 |
| 1-3 | Inventive | 0.159 | 0.164 | 2.56 | 0.049 | 6.51 |
| 1-4 | Inventive | 0.148 | 0.136 | 2.27 | 0.051 | 7.09 |

It can be seen from Table 2b that inventive device 1-2, using anthracene host Inv- 1 in the LEL, affords significantly lower voltage relative to comparative device 1-1, which uses C-1 host material, although the color of light produced is different. In device 1-3 and 1-4 the thickness of the LEL and ETL are changed resulting in a change in the color of light produced by the device relative to 1-2. Device 1-3 affords very similar color output to that of comparative device 1-1 but the luminance yield and efficiency are higher and the voltage is lower. Device 1-4 produces light that is bluer than device 1-1 and the device has higher efficiency.

### EXAMPLE 4

### Fabrication of Device 2-1 through 2-4.

A series of EL devices (2-1 through 2-4) were constructed in the same manner as device 1-1 through 1-4. Device 2-1 was the same as device 1-1 and has C-₁ as the host material in the LEL. Device 2-2 is the same as device 1-2, except Inv-1 was replaced with Inv-2 in the LEL. In device 2-3 and 2-4, Inv-2 is the host material in the LEL and the thickness of the LEL and ETL as well as the emitter level are varied relative to device 2-2. See Table 3a for the composition and thickness of the LEL and ETL. The devices were tested for luminous efficiency, color, and voltage at an operating current of 20 mA/cm² and the results are reported in Table 3b.

TABLE 3a
The LEL and ETL for Devices 2-1 through 2-4.

| | | | LEL | | Emitter | | ETL |
|---|---|---|---|---|---|---|---|
| | | LEL | Thick. | Emit- | Level | ETL | Thick. |
| Device | Example | Host | (nm) | ter | (%) | Material | (nm) |
| 2-1 | Com- | C-1 | 20 | D-1 | 0.75 | Alq | 35 |
| | parative | | | | | | |
| 2-2 | Inventive | Inv-2 | 20 | D-1 | 0.75 | Alq | 35 |
| 2-3 | Inventive | Inv-2 | 30 | D-1 | 0.50 | Alq | 25 |
| 2-4 | Inventive | Inv-2 | 40 | D-1 | 0.40 | Alq | 15 |

TABLE 3b
Evaluation results for Devices 2-1 through 2-4.

| | | | | Lum. | | |
|---|---|---|---|---|---|---|
| | | | | Yield | Eff. | Voltage |
| Device | Example | CIEx | CIEy | (cd/A) | (W/A) | (V) |
| 2-1 | Comparative | 0.165 | 0.172 | 2.40 | 0.040 | 6.60 |
| 2-2 | Inventive | 0.209 | 0.273 | 2.44 | 0.030 | 5.80 |
| 2-3 | Inventive | 0.179 | 0.201 | 1.99 | 0.032 | 5.76 |
| 2-4 | Inventive | 0.157 | 0.151 | 1.54 | 0.032 | 6.05 |

As can be seen from Table 3b, inventive devices having Inv-2 as the host in the LEL provide lower drive voltage relative to the comparison device 2-1 using C-1 as the host material.

### EXAMPLE 5

### Fabrication of Device 3-1 through 3-4.

Device 3-1 and 3-2 were constructed in the following manner.
1. A glass substrate coated with a 21.5 nm layer of indium-tin oxide (ITO), as the anode, was sequentially ultrasonicated in a commercial detergent, rinsed in deionized water, degreased in toluene vapor and exposed to oxygen plasma for about 1 min.
2. Over the ITO was deposited a 1 nm fluorocarbon (CFx) hole-injecting layer (HIL) by plasma-assisted deposition of CHF₃ as described in U.S. Pat. No. 6,208,075.
3. Next a layer of hole-transporting material 4,4′-Bis[N-(1-naphthyl)-N-phenylamino]biphenyl (NPB) was deposited to a thickness of 75 nm.
4. A light-emitting layer (LEL) corresponding to Inv-1 at a thickness 20 nm and including light-emitting material, D-1, at a level of 0.75% of the layer by volume was then deposited.
5. A first electron-transporting layer (ETL-1) composed of C-1 and having a thickness of either 34 or 33 nm (see Table 4a) was deposited over the LEL.
6. A second electron-transporting layer (ETL) of tris(8-quinolinolato)aluminum (III) (Alq), was vacuum-deposited over the ETL-1. The thickness of the ETL was adjusted (Table 4a) so that the each device fabricated had the same overall device thickness.
7. 0.5 nm layer of lithium fluoride was vacuum deposited onto the ETL, followed by a 150 nm layer of aluminum, to form a cathode layer.

The above sequence completed the deposition of the EL device. The device was then hermetically packaged in a dry glove box for protection against ambient environment.

Devices 3-3 and 3-4 were constructed in the same manner as device 3-1 and 3-2, except Inv-1 was replaced with Inv-2 (see Table 4a). The devices were tested for luminance yield, efficiency, drive voltage and the color of light produced and the results are reported in Table 4b.

TABLE 4a
The LEL and ETL for Devices 3-i through 3-4.

| | | | LEL | | ETL-1 | | ETL |
|---|---|---|---|---|---|---|---|
| | Ex- | LEL | Thick. | ETL-1 | Thick. | ETL | Thick. |
| Device | ample | Host | (nm) | Material | (nm) | Material | (nm) |
| 3-1 | In- | Inv-1 | 20 | C-1 | 34 | Alq | 1.0 |
| | ventive | | | | | | |
| 3-2 | In- | Inv-1 | 20 | C-1 | 33 | Alq | 2.0 |
| | ventive | | | | | | |
| 3-3 | In- | Inv-2 | 20 | C-1 | 34 | Alq | 1.0 |
| | ventive | | | | | | |
| 3-4 | In- | Inv-2 | 20 | C-1 | 33 | Alq | 2.0 |
| | ventive | | | | | | |

TABLE 4b
Evaluation results for Devices 3-1 through 3-4.

| | | | | Lum. | | |
|---|---|---|---|---|---|---|
| | | | | Yield | Eff. | Voltage |
| Device | Example | CIEx | CIEy | (cd/A) | (W/A) | (V) |
| 3-1 | Inventive | 0.143 | 0.143 | 3.34 | 0.080 | 6.38 |
| 3-2 | Inventive | 0.129 | 0.128 | 3.96 | 0.095 | 5.49 |
| 3-3 | Inventive | 0.142 | 0.114 | 3.53 | 0.093 | 5.73 |
| 3-4 | Inventive | 0.142 | 0.113 | 4.01 | 0.106 | 5.21 |

The devices prepared in this format, having a LEL including an inventive compound, a first electron-transporting layer including an anthracene derivative and a second electron-transporting layer of Alq, afford very high luminance. The devices have nearly twice the luminance yield and efficiency of similar devices from examples 3 and 4. In addition, the devices have a relatively low drive voltage and produce light having a good blue color.

The entire contents of the patents and other publications referred to in this specification are incorporated herein by reference. The invention has been described in detail with particular reference to certain preferred embodiments thereof, but it will be understood that variations and modifications can be effected within the spirit and scope of the invention.

### PARTS LIST

101 Substrate
103 Anode
105 Hole-Injecting layer (HIL)
107 Hole-Transporting Layer (HTL)
109 Light-Emitting layer (LEL)
111 Electron-Transporting layer (ETL)
112 Electron-Injecting layer (EIL)
113 Cathode
150 Power Source
160 Conductor

1. An OLED device comprising a cathode, an anode, and having therebetween a light emitting layer containing a host material and an emitting dopant material wherein the host includes a monoanthracene compound bearing aromatic groups in the 2-, 9-, and 10-positions and being further substituted or not with electron donating groups sufficient so as to provide an anthracene derivative that exhibits a measured oxidation potential of less than 1.28 V.

2. The device of claim 1 wherein the anthracene derivative exhibits an oxidation potential of less than 1.25 V.

3. The device of claim 1 wherein the anthracene derivative exhibits an oxidation potential of 1.20 V or less.

4. The device of claim 1 wherein the anthracene derivative exhibits an oxidation potential between 1.10 V and 1.25 V.

5. The device of claim 1 wherein the anthracene derivative bears at least one substituent with a σp value in the range of −0.25 to -0.50.

6. The device of claim 1 wherein the anthracene derivative does not bear any substituent with a σp value less than −0.50.

7. The device of claim 1 wherein the anthracene derivative bears an aromatic group in the 2-position that is further substituted with an alkoxy group.

8. The device of claim 1 wherein the anthracene derivative bears a hydrogen or alkyl group in the 6-position.

9. The device of claim 1 wherein the anthracene derivative bears a naphthyl group or a biphenyl group in the 9-position and a naphthyl group or a biphenyl group in the 10-position.

10. The device of claim 1 wherein the anthracene derivative is represented by Formula (1): 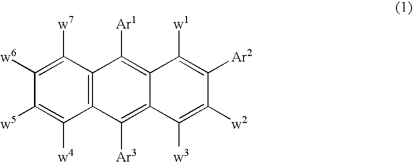
wherein:
Ar¹, Ar², and Ar³ are the same or different, and each represents an aromatic group;
w¹ through w⁷ represent hydrogen or a substituent.

11. The device of claim 10 wherein at least one of Ar¹, Ar², and Ar³ bears a substituent with a σp value of −0.25 or lower.

12. The device of claim 1 wherein the anthracene derivative is represented by Formula (2): 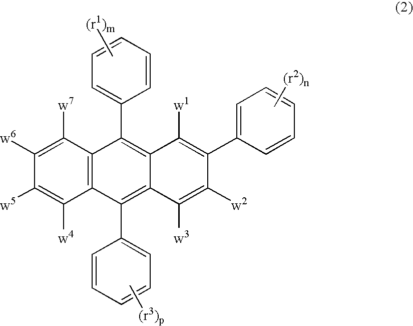
wherein:
each r¹, r², and r³ are the same or different, and each represents a substituent group, provided adjacent substituents may combine to form a ring group, and provided at least one of r¹, r², and r³ represents a group with a up value in the range of −0.25 to −0.50;
m, n, and p are independently 0-5, provided m, n, and p are not all 0; and
w¹ through w⁷ represent hydrogen or a substituent.

13. The device of claim 12 wherein at least one r³ has a σp value of −0.25 or lower.

14. The device of claim 1 wherein the emitting dopant material comprises a boron atom.

15. The device of claim 1 including a further layer located between the light-emitting layer and the cathode wherein the further layer includes an electron-transporting material having an anthracene or tetracene nucleus.

16. The device of claim 15 wherein the electron-transporting material in the further layer includes an anthracene nucleus substituted with aromatic groups in the 2-, 9-, and 10-positions.

17. The device of claim 15 wherein an additional layer is located between the further layer and the cathode and wherein the additional layer includes a material comprising a phenanthroline nucleus or a metal complex comprising an 8-quinolinolate nucleus.

18. An OLED device comprising a cathode, an anode, and having therebetween a light emitting layer containing a host material and an emitting dopant material wherein the host includes an anthracene compound bearing aromatic groups in the 9-, and 10-positions and including an aromatic group having no more than two fused rings in the 2-position and said anthracene compound being further substituted or not with electron donating groups sufficient so as to provide an anthracene derivative that exhibits an oxidation potential of less than 1.25 V.

19. The device of claim 18 wherein the anthracene compound exhibits an oxidation potential of 1.20 V or less.

20. The device of claim 18 including a further layer located between the light-emitting layer and the cathode wherein the further layer includes an electron-transporting material comprising an anthracene nucleus.
